(19) United States
(12) Patent Application Publication
(10) Pub. No.: US 2026/0282405 A1
(43) Pub. Date: Sep. 17, 2026

(54) EXTENDED MULTI-SIDED STORAGE NODES IN THREE-DIMENSIONAL (3D) MEMORY

(71) Applicant: Micron Technology, Inc., Boise, ID (US)

(72) Inventors: Qitao Fu, Singapore (SG); Jeong-Heon Choi, Boise, ID (US); Jake Soares, Boise, ID (US); Frank Speetjens, Boise, ID (US); Dojun Kim, Boise, ID (US); Vassil N. Antonov, Boise, ID (US)

(21) Appl. No.: 19/558,875

(22) Filed: Mar. 6, 2026

Related U.S. Application Data
(60) Provisional application No. 63/770,064, filed on Mar. 11, 2025.

(51) Int. Cl. H10D 1/68; H10B 12/00; H10W 20/44; H10P 14/40; H10P 14/43

(52) U.S. Cl. CPC H10D 1/714; H10B 12/03; H10D 1/692; H10D 1/696; H10W 20/4451; H10P 14/414; H10P 14/432

(57) ABSTRACT

Methods and apparatuses are provided for extended multi-sided storage nodes in three-dimensional memory. An array includes vertically stacked memory cells, horizontally oriented access devices having gates formed horizontally at a different level from each other, channel regions, first source/drain regions and second source/drain regions separated by the channel regions. The horizontally oriented storage nodes include a first electrode extending in a horizontal direction, a semiconductor material in contact with the second source/drain region of a given one of the vertically stacked memory cells, and a conductive element of a different type than the first electrode formed on an end surface of the first electrode, a dielectric material formed on the first electrode and the conductive element, and a second electrode separated from the first electrode by the dielectric material, wherein the second electrode is formed continuously in a vertical direction along the vertically stacked memory cells.

### PRIORITY INFORMATION

This application claims the benefit of U.S. Provisional Application Number 63/770,064, filed on March 11, 2025, the contents of which are incorporated herein by reference.

### TECHNICAL FIELD

The present disclosure relates generally to memory devices, and more particularly, to extended multi-sided storage nodes in three dimensional (3D) memory.

### BACKGROUND

Memory is often implemented in electronic systems, such as computers, cell phones, hand-held devices, etc. There are many different types of memory, including volatile and non-volatile memory. Volatile memory may require power to maintain its data and may include random-access memory (RAM), dynamic random-access memory (DRAM), static random-access memory (SRAM), and synchronous dynamic random-access memory (SDRAM). Non-volatile memory may provide persistent data by retaining stored data when not powered and may include NAND flash memory, NOR flash memory, nitride read only memory (NROM), phase-change memory (e.g., phase-change random access memory), resistive memory (e.g., resistive random-access memory), cross-point memory, ferroelectric random-access memory (FeRAM), or the like.

As design rules shrink, less semiconductor space is available to fabricate memory, including DRAM arrays. A respective memory cell for DRAM may include an access device, e.g., transistor, having a first and a second source/drain region separated by a channel region. A gate may oppose the channel region and be separated therefrom by a gate dielectric. An access line, such as a word line, is electrically connected to the gate of the DRAM memory cell. A DRAM memory cell can include a storage node, such as a capacitor cell, electrically connected by the access device to a sense line, such as a digit line. The access device can be activated (e.g., to select the cell) by an access line electrically connected to the access device. The capacitor can store a charge corresponding to a data value of a respective memory cell (e.g., a logic “1” or “0”).

### BRIEF DESCRIPTION OF THE DRAWINGS

FIG. 1A is a schematic illustration of a horizontal access device in a vertical three-dimensional (3D) memory in accordance with a number of embodiments of the present disclosure.

FIG. 1B is a perspective view illustrating a portion of a horizontal access device in vertical three-dimensional (3D) memory in accordance with a number of embodiments of the present disclosure.

FIG. 2 illustrates a portion of a horizontal access device in vertical three-dimensional (3D) memory in accordance with a number of embodiments of the present disclosure.

FIG. 3 is a perspective view of a memory device in accordance with a number of embodiments of the present disclosure.

FIG. 4 is a cross-sectional view of a vertical stack in vertical three-dimensional (3D) memory in accordance with a number of embodiments of the present disclosure.

FIG. 5A illustrates an example method, at one stage of a semiconductor fabrication process, for forming extended multi-sided storage nodes in vertical 3D memory, in accordance with a number of embodiments of the present disclosure.

FIG. 5B is a cross sectional view, taken along cut-line A-A’ in FIG. 5A, showing another view of the semiconductor structure at a particular time in the semiconductor fabrication process for forming extended multi-sided storage nodes in vertical 3D memory, in accordance with a number of embodiments of the present disclosure.

FIG. 6A illustrates an example method, at another stage of a semiconductor fabrication process for forming extended multi-sided storage nodes in vertical 3D memory, in accordance with a number of embodiments of the present disclosure.

FIG. 6B illustrates a cross sectional view, taken along cut-line B-B’ in FIG. 6A, showing another view of the semiconductor structure at this particular point in one example semiconductor fabrication process for forming extended multi-sided storage nodes in vertical 3D memory, in accordance with a number of embodiments of the present disclosure.

FIG. 6C illustrates a cross sectional view, taken along cut-line C-C’ in FIG. 6A, showing another view of the semiconductor structure at this particular point in one ex ample semiconductor fabrication process of an embodiment of the present disclosure.

FIG. 6D illustrates a cross sectional view, taken along cut-line A-A’ in FIG. 6A, showing another view of the semiconductor structure at this particular point in one example semiconductor fabrication process for forming extended multi-sided storage nodes in vertical 3D memory, in accordance with a number of embodiments of the present disclosure.

FIG. 7A illustrates an example method, at another stage of a semiconductor fabrication process, for forming extended multi-sided storage nodes in vertical 3D memory, in accordance with a number of embodiments of the present disclosure.

FIG. 7B illustrates an example method, at another stage of a semiconductor fabrication process, for forming extended multi-sided storage nodes in vertical 3D memory, in accordance with a number of embodiments of the present disclosure.

FIG. 8 illustrates an example method, at another stage of a semiconductor fabrication process, for forming extended multi-sided storage nodes in vertical 3D memory, in accordance with a number of embodiments of the present disclosure.

FIG. 9A illustrates an example method, at one stage of a semiconductor fabrication process, for forming extended multi-sided storage nodes in vertical 3D memory, in accordance with a number of embodiments of the present disclosure.

FIG. 9B illustrates an example method, at one stage of a semiconductor fabrication process, for forming extended multi-sided storage nodes in vertical 3D memory, in accordance with a number of embodiments of the present disclosure.

FIG. 9C illustrates an example method, at one stage of a semiconductor fabrication process, for forming extended multi-sided storage nodes in vertical 3D memory, in accordance with a number of embodiments of the present disclosure.

FIG. 9D illustrates an example method, at one stage of a semiconductor fabrication process, for forming extended multi-sided storage nodes in vertical 3D memory, in accordance with a number of embodiments of the present disclosure.

FIG. 9E illustrates an example method, at one stage of a semiconductor fabrication process, for forming extended multi-sided storage nodes in vertical 3D memory, in accordance with a number of embodiments of the present disclosure.

FIG. 9F illustrates an example method, at one stage of a semiconductor fabrication process, for forming extended multi-sided storage nodes in vertical 3D memory, in accordance with a number of embodiments of the present disclosure.

FIG. 9G illustrates an example method, at one stage of a semiconductor fabrication process, for forming extended multi-sided storage nodes in vertical 3D memory, in accordance with a number of embodiments of the present disclosure.

FIG. 9H illustrates an example method, at one stage of a semiconductor fabrication process, for forming extended multi-sided storage nodes in vertical 3D memory, in accordance with a number of embodiments of the present disclosure.

FIG. 9I illustrates an example method, at one stage of a semiconductor fabrication process, for forming extended multi-sided storage nodes in vertical 3D memory, in accordance with a number of embodiments of the present disclosure.

FIG. 9J-1 illustrates a cross-sectional view of a portion of a vertical three-dimensional (3D) memory with extended multi-sided storage nodes in accordance with a number of embodiments of the present disclosure.

FIG. 9J-2 illustrates an end-on cross-sectional view of the portion of the vertical three-dimensional (3D) memory illustrated in FIG. 9A-1 in accordance with a number of embodiments of the present disclosure.

FIG. 10A illustrates an example method, at one stage of a semiconductor fabrication process, for forming extended multi-sided storage nodes in vertical 3D memory, in accordance with a number of embodiments of the present disclosure.

FIG. 10B illustrates an example method, at one stage of a semiconductor fabrication process, for forming extended multi-sided storage nodes in vertical 3D memory, in accordance with a number of embodiments of the present disclosure.

FIG. 10C illustrates an example method, at one stage of a semiconductor fabrication process, for forming extended multi-sided storage nodes in vertical 3D memory, in accordance with a number of embodiments of the present disclosure.

FIG. 10D illustrates an example method, at one stage of a semiconductor fabrication process, for forming extended multi-sided storage nodes in vertical 3D memory, in accordance with a number of embodiments of the present disclosure.

FIG. 10E illustrates an example method, at one stage of a semiconductor fabrication process, for forming extended multi-sided storage nodes in vertical 3D memory, in accordance with a number of embodiments of the present disclosure.

FIG. 10F illustrates an example method, at one stage of a semiconductor fabrication process, for forming extended multi-sided storage nodes in vertical 3D memory, in accordance with a number of embodiments of the present disclosure.

FIG. 10G-1 illustrates a cross-sectional view of a portion of a vertical three-dimensional (3D) memory with extended multi-sided storage nodes in accordance with a number of embodiments of the present disclosure.

FIG. 10G-2 illustrates an end-on cross-sectional view of the portion of the vertical three-dimensional (3D) memory illustrated in FIG. 10A-1 in accordance with a number of embodiments of the present disclosure.

FIG. 11 is a block diagram of an apparatus in the form of a computing system including a memory device in accordance with a number of embodiments of the present disclosure.

### DETAILED DESCRIPTION

Embodiments of the present disclosure describe forming extended multi-sided storage nodes in vertical three dimensional (3D) memory. As referred to herein, a multi-sided storage node (e.g., capacitor) is a storage node that includes a first electrode that extends horizontally from a source/drain region and includes interior and exterior surfaces, and a second electrode that is separated from both the interior and the exterior surfaces of the first electrode. In some embodiments, the second electrode is formed continuously in a vertical direction along a plurality of vertically stacked memory cells.

Compared to single-sided storage nodes, for instance, multi-sided storage nodes in accordance with the present disclosure provide an increased effective capacitance and a high capacitance per cell. Additionally, embodiments herein provide storage nodes that have high storage capacitance without increasing the size of the storage nodes. Stated differently, embodiments herein can provide an increased efficiency for memory cells without a corresponding increase in the size of the cells.

The present disclosure makes reference to junctions between storage nodes and source/drain regions in memory devices. These junctions are sometimes referred to herein as “cell contact junctions.”

Previous approaches to forming multi-sided storage nodes can damage the TiN material used to form the first electrode because the TiN material is exposed to the etchant used to remove the SiGe during the formation of the multi-sided storage nodes. This can lead to the storage node that comprises the damaged first electrode to have a decreased capacity to store a charge due to the decreased TiN material.

Embodiments of the present disclosure, however, improve upon previous approaches by forming a conductive element onto exposed surfaces of the first electrode to extend the first electrode and first material to an original formation length. Forming the conductive element on the first electrode as described herein increases the surface area of the first electrode compared to previous approaches and; therefore, provide a more accurate read of the charge stored on the first electrode.

“Silicide” or “silicide material,” as referred to herein, is a material comprising silicon and an element more electropositive than silicon. For example, “silicide” can refer to titanium silicide, zirconium silicide, hafnium silicide, molybdenum silicide, tungsten silicide, ruthenium silicide, platinum silicide, etc.

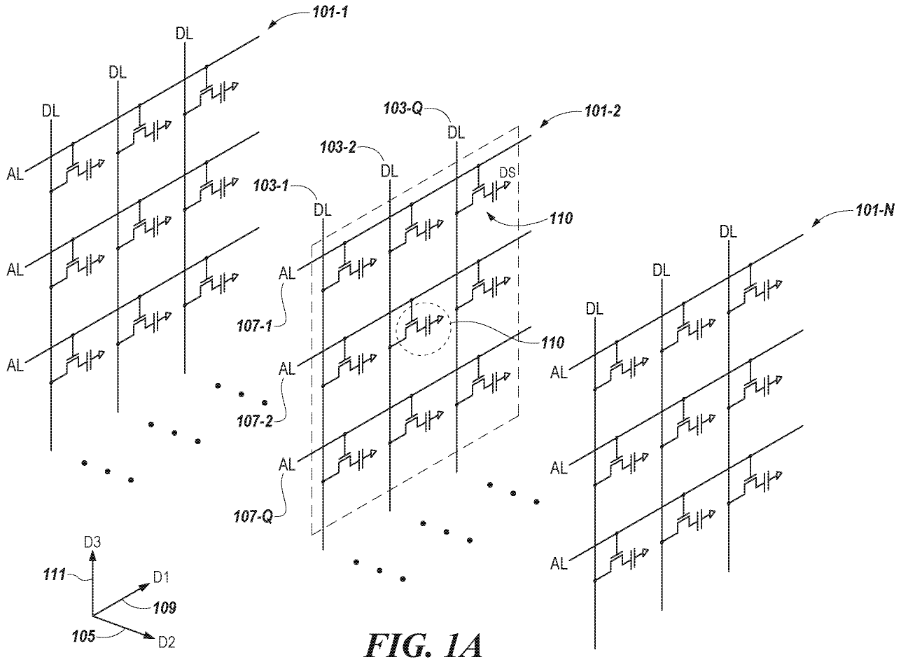

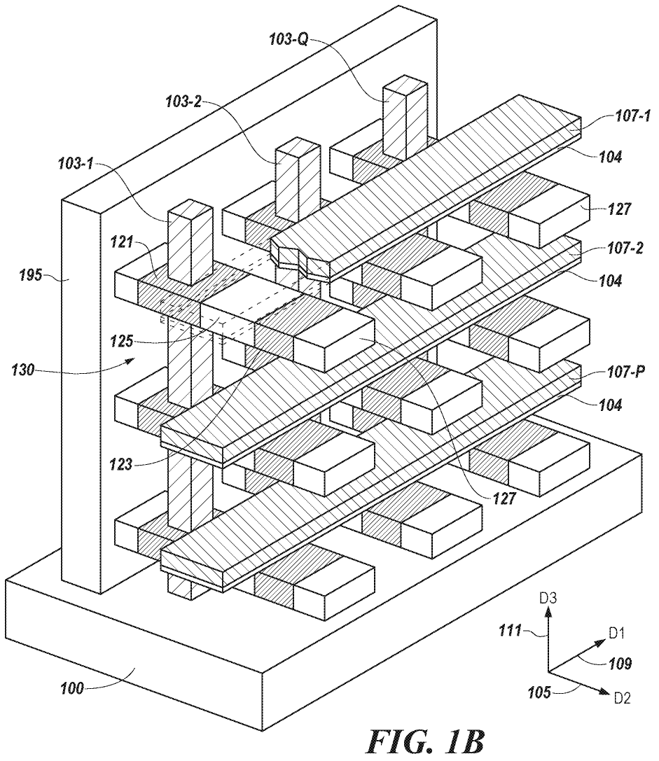

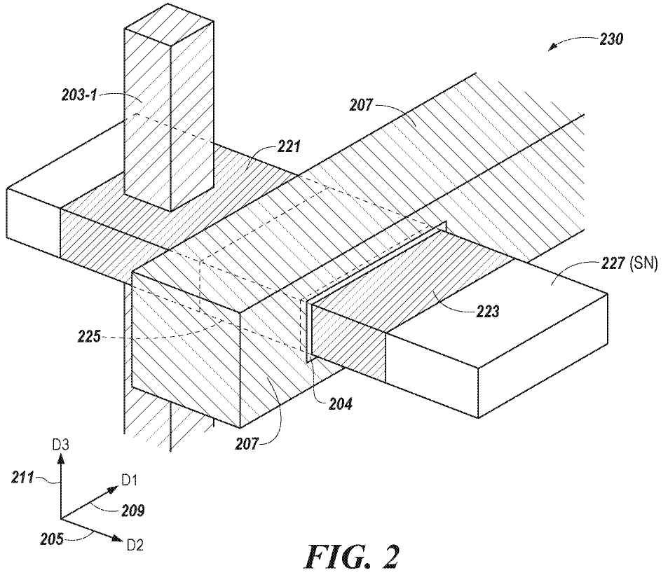

The figures herein follow a numbering convention in which the first digit or digits correspond to the figure number of the drawing and the remaining digits identify an element or component in the drawing. Similar elements or components between different figures may be identified by the use of similar digits. For example, reference numeral 104 may reference element “04” in FIG. 1, and a similar element may be referenced as 204 in FIG. 2. Multiple analogous elements within one figure may be referenced with a reference numeral followed by a hyphen and another numeral or a letter. For example, 302-1 may reference element 302-1 in FIG. 3 and 302-2 may reference element 302-2, which may be analogous to element 302-1. Such analogous elements may be generally referenced without the hyphen and extra numeral or letter. For example, elements 302-1 and 302-2 or other analogous elements may be generally referenced as 302.

FIG. 1A is a schematic illustration of a horizontal access device in a vertical three-dimensional (3D) memory in accordance with a number of embodiments of the present disclosure. FIG. 1A illustrates a circuit diagram showing a cell array of a 3D semiconductor memory device according to embodiments of the present disclosure. FIG. 1A illustrates that a cell array may have a plurality of sub cell arrays 101-1, 101-2, . . ., 101-N. The sub cell arrays 101-1, 101-2, . . ., 101-N may be arranged along a second direction (D2) 105. Each of the sub cell arrays, e.g., sub cell array 101-2, may include a plurality of access lines 107-1, 107-2, . . ., 107-Q (which also may be referred to as word lines). Also, each of the sub cell arrays, e.g., sub cell array 101-2, may include a plurality of digit lines 103-1, 103-2, . . ., 103-Q (which also may be referred to as bit lines, data lines, or sense lines). In FIG. 1A, the access lines 107-1, 107-2, . . ., 107-Q are illustrated extending in a first direction (D1) 109 and the digit lines 103-1, 103-2, . . ., 103-Q are illustrated extending in a third direction (D3) 111. According to embodiments, the first direction (D1) 109 and the second direction (D2) 105 may be considered in a horizontal (“X-Y”) plane. The third direction (D3) 111 may be considered in a vertical (“Z”) plane. Hence, according to embodiments described herein, the digit lines 103-1, 103-2, . . ., 103-Q are extending in a vertical direction, e.g., third direction (D3) 111.

A memory cell, e.g., memory cell 110, may include an access device, e.g., access transistor, and a storage node located at an intersection of each access line 107-1, 107-2, . . ., 107-Q and each digit line 103-1, 103-2, . . ., 103-Q. Memory cells may be written to, or read from, using the access lines 107-1, 107-2, . . ., 107-Q and digit lines 103-1, 103-2, . . ., 103-Q. The access lines 107-1, 107-2, . . ., 107-Q may conductively interconnect memory cells along horizontal rows of each sub cell array 101-, 101-2, . . ., 101-N, and the digit lines 103-1, 103-2, . . ., 103-Q may conductively interconnect memory cells along vertical columns of each sub cell array 101-, 101-2, . . ., 101-N. One memory cell, e.g., 110, may be located between one access line, e.g., 107-2, and one digit line, e.g., 103-2. Each memory cell may be uniquely addressed through a combination of an access line 107-1, 107-2, . . ., 107-Q and a digit line 103-1, 103-2, . . ., 103-Q.

The access lines 107-1, 107-2, . . ., 107-Q may be or include conducting patterns (e.g., metal lines) disposed on and spaced apart from a substrate. The access lines 107-1, 107-2, . . ., 107-Q may extend in a first direction (D1) 109. The access lines 107-1, 107-2, . . ., 107-Q in one sub cell array, e.g., 101-2, may be spaced apart from each other in a vertical direction, e.g., in a third direction (D3) 111.

The digit lines 103-1, 103-2, . . ., 103-Q may be or include conductive patterns (e.g., metal lines) extending in a vertical direction with respect to the substrate, e.g., in a third direction (D3) 111. The digit lines in one sub cell array, e.g., 101-2, may be spaced apart from each other in the first direction (D1) 109.

A gate of a memory cell, e.g., memory cell 110, may be connected to an access line, e.g., 107-2, and a first conductive node, e.g., first source/drain region, of an access device, e.g., transistor, of the memory cell 110 may be connected to a digit line, e.g., 103-2. Each of the memory cells, e.g., memory cell 110, may be connected to a storage node (e.g., capacitor). A second conductive node, e.g., second source/drain region of the access device, e.g., transistor, of the memory cell 110 may be connected to the storage node. While first and second source/drain region references are used herein to denote two separate and distinct source/drain regions, it is not intended that the source/drain region referred to as the “first” and/or “second” source/drain regions have some unique meaning. It is intended only that one of the source/drain regions is connected to a digit line, e.g., 103-2, and the other may be connected to a storage node.

FIG. 1B is a perspective view illustrating a portion of a horizontal access device in vertical three-dimensional (3D) memory, e.g., a portion of a sub cell array 101-2 shown in FIG. 1A as a vertically oriented stack of memory cells in an array, in accordance with a number of embodiments of the present disclosure.

As shown in FIG. 1B, a substrate 100 may have formed thereon one of the pluralities of sub cell arrays, e.g., 101-2, described in connection with FIG. 1A. For example, the substrate 100 may be or include a silicon substrate, a germanium substrate, or a silicon-germanium substrate, etc. Embodiments, however, are not limited to these examples.

As shown in the example embodiment of FIG. 1B, the substrate 100 may have fabricated thereon a vertically oriented stack of memory cells, e.g., memory cell 110 in FIG. 1A, extending in a vertical direction, e.g., third direction (D3) 111. According to some embodiments the vertically oriented stack of memory cells may be fabricated such that each memory cell, e.g., memory cell 110 in FIG. 1A, is formed on plurality of vertical levels, e.g., a first level (L1) 197-1, a second level (L2) 197-2, and a third level (L3) 197-3. The plurality of vertical levels can include any number of levels up to an uppermost Nth level. Vertical levels can also be referred to as tiers in vertically oriented stack of memory cells. The repeating, vertical levels, L1, L2, and L3, may be arranged, e.g., “stacked”, a vertical direction, e.g., third direction (D3) 111 shown in FIG. 1A, and may be separated from the substrate 100 by an insulator material. Each of the repeating, vertical levels, L1, L2, and L3 may include a plurality of discrete components, e.g., regions, to the horizontally oriented access devices 130, e.g., transistors, and storage nodes (e.g., capacitors) including access line 107-1, 107-2, . . ., 107-Q connections and digit line 103-1, 103-2, . . ., 103-Q connections. The plurality of discrete components to the horizontally oriented access devices 130, e.g., transistors, may be formed in a plurality of iterations of vertically, repeating layers within each level, as described in more detail below, and may extend horizontally in the second direction (D2) 105, analogous to second direction (D2) 105 shown in FIG. 1A.

The plurality of discrete components to the laterally oriented access devices 130, e.g., transistors, may include a first source/drain region 121 and a second source/drain region 123 separated by a channel region 125, extending laterally in the second direction (D2) 105, and formed in a body of the access devices. In some embodiments, the channel region 125 may include silicon, germanium, silicon-germanium, and/or indium gallium zinc oxide (IGZO). In some embodiments, the first and the second source/drain regions, 121 and 123, can include an n-type dopant region formed in a p-type doped body to the access device to form an n-type conductivity transistor. In some embodiments, the first and the second source/drain regions, 121 and 123, may include a p-type dopant formed within an n-type doped body to the access device to form a p-type conductivity transistor. By way of example, and not by way of limitation, the n-type dopant may include phosphorous (P) atoms and the p-type dopant may include atoms of boron (B) formed in an oppositely doped body region of polysilicon semiconductor material. Embodiments, however, are not limited to these examples.

The storage node 127 may be connected to one respective end of the access device. As shown in FIG. 1B, the storage node 127 may be connected to the second source/drain region 123 of the access device. The storage node may be or include memory elements capable of storing data. Each of the storage nodes may be a memory element using one of a capacitor, a magnetic tunnel junction pattern, and/or a variable resistance body which includes a phase change material, etc. Embodiments, however, are not limited to these examples. In some embodiments, the storage node associated with each access device of a unit cell, e.g., memory cell 110 in FIG. 1A, may similarly extend in the second direction (D2) 105, analogous to second direction (D2) 105 shown in FIG. 1A.

As shown in FIG. 1B a plurality of horizontally oriented access lines 107-1, 107-2, . . ., 107-Q extend in the first direction (D1) 109, analogous to the first direction (D1) 109 in FIG. 1A. The plurality of horizontally oriented access lines 107-1, 107-2, . . ., 107-Q may be analogous to the access lines 107-1, 107-2, . . ., 107-Q shown in FIG. 1A. The plurality of horizontally oriented access lines 107-1, 107-2, . . ., 107-Q may be arranged, e.g., “stacked”, along the third direction (D3) 111. The plurality of horizontally oriented access lines 107-1, 107-2, . . ., 107-Q may include a conductive material. For example, the conductive material may include one or more of a doped semiconductor, e.g., doped silicon, doped germanium, etc., a conductive metal nitride, e.g., titanium nitride, tantalum nitride, etc., a metal, e.g., tungsten (W), titanium (Ti), tantalum (Ta), ruthenium (Ru), cobalt (Co), molybdenum (Mo), etc., and/or a metal-semiconductor compound, e.g., tungsten silicide, cobalt silicide, titanium silicide, etc. Embodiments, however, are not limited to these examples.

Among each of the vertical levels, (L1), (L2), and (L3), the horizontally oriented memory cells, e.g., memory cell 110 in FIG. 1A, may be spaced apart from one another horizontally in the first direction (D1) 109. However, the plurality of discrete components to the horizontally oriented access devices 130, e.g., first source/drain region 121 and second source/drain region 123 separated by a channel region 125, extending laterally in the second direction (D2) 105, and the plurality of horizontally oriented access lines 107-1, 107-2, . . ., 107-Q extending laterally in the first direction (D1) 109, may be formed within different vertical layers within each level. For example, the plurality of horizontally oriented access lines 107-1, 107-2, . . ., 107-Q, extending in the first direction (D1) 109, may be formed on a top surface opposing and electrically coupled to the channel regions 125, separated therefrom by a gate dielectric, and orthogonal to horizontally oriented access devices 130, e.g., transistors, extending in laterally in the second direction (D2) 105. In some embodiments, the plurality of horizontally oriented access lines 107-1, 107-2, . . ., 107-Q, extending in the first direction (D1) 109 are formed in a higher vertical layer, farther from the substrate 100, within a level, e.g., within level (L1), than a layer in which the discrete components, e.g., first source/drain region 121 and second source/drain region 123 separated by a channel region 125, of the horizontally oriented access device are formed.

As shown in the example embodiment of FIG. 1B, the digit lines, 103-1, 103-2, . . ., 103-Q, extend in a vertical direction with respect to the substrate 100, e.g., in a third direction (D3) 111. Further, as shown in FIG. 1B, the digit lines, 103-1, 103-2, . . ., 103-Q, in one sub cell array, e.g., sub cell array 101-2 in FIG. 1A, may be spaced apart from each other in the first direction (D1) 109. The digit lines, 103-1, 103-2, . . ., 103-Q, may be provided, extending vertically relative to the substrate 100 in the third direction (D3) 111 in vertical alignment with source/drain regions to serve as first source/drain regions 121 or, as shown, be vertically adjacent first source/drain regions 121 for each of the horizontally oriented access devices 130, e.g., transistors, extending laterally in the second direction (D2) 105, but adjacent to each other on a level, e.g., first level (L1), in the first direction (D1) 109. Each of the digit lines, 103-1, 103-2, . . ., 103-Q, may vertically extend, in the third direction (D3), on sidewalls, adjacent first source/drain regions 121, of respective ones of the plurality of horizontally oriented access devices 130, e.g., transistors, that are vertically stacked. In some embodiments, the plurality of vertically oriented digit lines 103-1, 103-2, . . ., 103-Q, extending in the third direction (D3) 111, may be connected to side surfaces of the first source/drain regions 121 directly and/or through additional contacts including metal silicides.

For example, a first one of the vertically extending digit lines, e.g., 103-1, may be adjacent a sidewall of a first source/drain region 121 to a first one of the horizontally oriented access devices 130, e.g., transistors, in the first level (L1), a sidewall of a first source/drain region 121 of a first one of the horizontally oriented access devices 130, e.g., transistors, in the second level (L2), and a sidewall of a first source/drain region 121 a first one of the horizontally oriented access devices 130, e.g., transistors, in the third level (L3), etc. Similarly, a second one of the vertically extending digit lines, e.g., 103-2, may be adjacent a sidewall to a first source/drain region 121 of a second one of the horizontally oriented access devices 130, e.g., transistors, in the first level (L1), spaced apart from the first one of horizontally oriented access devices 130, e.g., transistors, in the first level (L1) in the first direction (D1) 109. And the second one of the vertically extending digit lines, e.g., 103-2, may be adjacent a sidewall of a first source/drain region 121 of a second one of the laterally oriented access devices 130, e.g., transistors, in the second level (L2), and a sidewall of a first source/drain region 121 of a second one of the horizontally oriented access devices 130, e.g., transistors, in the third level (L3), etc. Embodiments are not limited to a particular number of levels.

The vertically extending digit lines, 103-1, 103-2, . . ., 103-Q, may include a conductive material, such as, for example, one of a doped semiconductor material, a conductive metal nitride, metal, and/or a metal-semiconductor compound. The digit lines, 103-1, 103-2, . . ., 103-Q, may correspond to digit lines (DL) described in connection with FIG. 1A.

As shown in the example embodiment of FIG. 1B, a conductive body contact may be formed extending in the first direction (D1) 109 along an end surface of the horizontally oriented access devices, e.g., transistors, in each level (L1), (L2), and (L3) above the substrate 100. The body contact may be connected to a body e.g., body region, of the horizontally oriented access devices, e.g., transistors, in each memory cell, e.g., memory cell 110 in FIG. 1A. The body contact may include a conductive material such as, for example, one of a doped semiconductor material, a conductive metal nitride, metal, and/or a metal-semiconductor compound.

Although not shown in FIG. 1B, an insulating material may fill other spaces in the vertically stacked array of memory cells. For example, the insulating material may include one or more of a silicon oxide material, a silicon nitride material, and/or a silicon oxynitride material, etc. Embodiments, however, are not limited to these examples.

FIG. 2 illustrates a portion of a horizontal access device in vertical three-dimensional (3D) memory in accordance with a number of embodiments of the present disclosure. FIG. 2 illustrates in more detail a unit cell, e.g., memory cell 110 in FIG. 1, of the vertically stacked array of memory cells, e.g., within a sub cell array 101-2 in FIG. 1, according to some embodiments of the present disclosure. As shown in FIG. 2, the first and the second source/drain regions, 221 and 223, may be impurity doped regions to the laterally oriented access devices 230, e.g., transistors. The first and the second source/drain regions may be separated by a channel region 225 formed in a body of semiconductor material, e.g., body region of the horizontally oriented access devices 230, e.g., transistors. The first and the second source/drain regions, 221 and 223, may be formed from an n-type or p-type dopant doped in the body region. However, embodiments are not so limited.

For example, for an n-type conductivity transistor construction the body region of the laterally oriented access devices 230, e.g., transistors, may be formed of a low doped p-type (p-) semiconductor material. In one embodiment, the body region and the channel region 225 separating the first and the second source/drain regions, 221 and 223, may include a low doped, p-type (e.g., low dopant concentration (p-)) polysilicon (Si) material consisting of boron (B) atoms as an impurity dopant to the polycrystalline silicon. The first and the second source/drain regions, 221 and 223, may also comprise a metal, and/or metal composite materials containing ruthenium (Ru), molybdenum (Mo), nickel (Ni), titanium (Ti), copper (Cu), a highly doped degenerate semiconductor material, and/or at least one of indium oxide (In2O₃), or indium tin oxide (In₂-xSnxO₃), formed using an atomic layer deposition process, etc. Embodiments, however, are not limited to these examples. As used herein, a degenerate semiconductor material is intended to mean a semiconductor material, such as polysilicon, containing a high level of doping with significant interaction between dopants, e.g., phosphorus (P), boron (B), etc. Non-degenerate semiconductors, by contrast, contain moderate levels of doping, where the dopant atoms are well separated from each other in the semiconductor host lattice with negligible interaction.

In this example, the first and the second source/drain regions, 221 and 223, may include a high dopant concentration, n-type conductivity impurity (e.g., high dopant (n+)) doped in the first and the second source/drain regions, 221 and 223. In some embodiments, the high dopant, n-type conductivity first and second drain regions 221 and 223 may include a high concentration of phosphorus (P) atoms deposited therein. Embodiments, however, are not limited to this example. In other embodiments, the horizontally oriented access devices 230, e.g., transistors, may be of a p-type conductivity construction in which case the impurity, e.g., dopant, conductivity types would be reversed.

As shown in FIG. 2, the first and the second source/drain regions, 221 and 223, may be impurity doped regions to the laterally oriented access devices 230, e.g., transistors. The first and the second source/drain regions may be separated by a channel region 225 formed in a body of semiconductor material, e.g., body region, of the horizontally oriented access devices 230, e.g., transistors. The first and the second source/drain regions, 221 and 223, may be formed from an n-type or p-type dopant doped in the body region. However, embodiments are not so limited.

The first source/drain region 221 may occupy an upper portion in the body of the laterally oriented access devices 230, e.g., transistors. For example, the first source/drain region 221 may have a bottom surface within the body of the horizontally oriented access device 230 which is located higher, vertically in the third direction (D3) 211, than a bottom surface of the body of the laterally, horizontally oriented access device 230. As such, the laterally, horizontally oriented access device 230 may have a body portion which is below the first source/drain region 221 and is in electrical contact with the body contact. Further, as shown in the example embodiment of FIG. 2, an access line, e.g., 207, analogous to the access lines 107-1, 107-2, . . ., 107-Q shown in FIG. 1, may disposed on a top surface opposing and coupled to a channel region 225, separated therefrom by a gate dielectric 204. The gate dielectric 204 may be, for example, a high-k dielectric material, a silicon oxide material, a silicon nitride material, a silicon oxynitride material, etc., or a combination thereof. Embodiments are not so limited. For example, in high-k dielectric material examples the gate dielectric material 304 may include one or more of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobite, etc.

As shown in the example embodiment of FIG. 2, a digit line, e.g., 203-1, analogous to the digit lines 103-1, 103-2, . . ., 103-Q in FIG. 1, may be vertically extending in the third direction (D3) 211 adjacent a sidewall of the first source/drain region 221 in the body to the horizontally oriented access devices 230, e.g., transistors horizontally conducting between the first and the second source/drain regions 221 and 223 along the second direction (D2) 205. In this embodiment, the vertically oriented digit line 203-1 is formed symmetrically, in vertical alignment, in electrical contact with the first source/drain region 221. The digit line 203-1 may be formed in contact with an insulator material such that there is no body contact within channel region 225.

As shown in the example embodiment of FIG. 2, the digit line 203-1 may be formed symmetrically within the first source/drain region 221 such that the first source/drain region 221 surrounds the digit line 203-1 all around. The first source/drain region 221 may occupy an upper portion in the body of the laterally oriented access devices 230, e.g., transistors. For example, the first source/drain region 221 may have a bottom surface within the body of the horizontally oriented access device 230 which is located higher, vertically in the third direction (D3) 211, than a bottom surface of the body of the laterally, horizontally oriented access device 230. As such, the laterally, horizontally oriented access device 230 may have a body portion which is below the first source/drain region 321 and is in contact with the body contact. An insulator material may fill the body contact such that the first source/drain region 221 may not be in electrical contact with channel region 225. Further, as shown in the example embodiment of FIG. 2, an access line, e.g., 207, analogous to the access lines 107-1, 107-2, . . ., 107-Q shown in FIG. 1, may disposed all around and coupled to a channel region 225, separated therefrom by a gate dielectric 204.

Although the digit line 203-1 is described above as being formed symmetrically within the first source/drain region 221 such that the first source/drain region 221 surrounds the digit line 203-1 all around, embodiments are not so limited. For instance, in some examples, the digit line 203-1 can be formed asymmetrically. In this embodiment, the vertically oriented digit line is formed asymmetrically adjacent in electrical contact with the first source/drain regions 221. The digit line may be formed asymmetrically to reserve room for a body contact in the channel region 225.

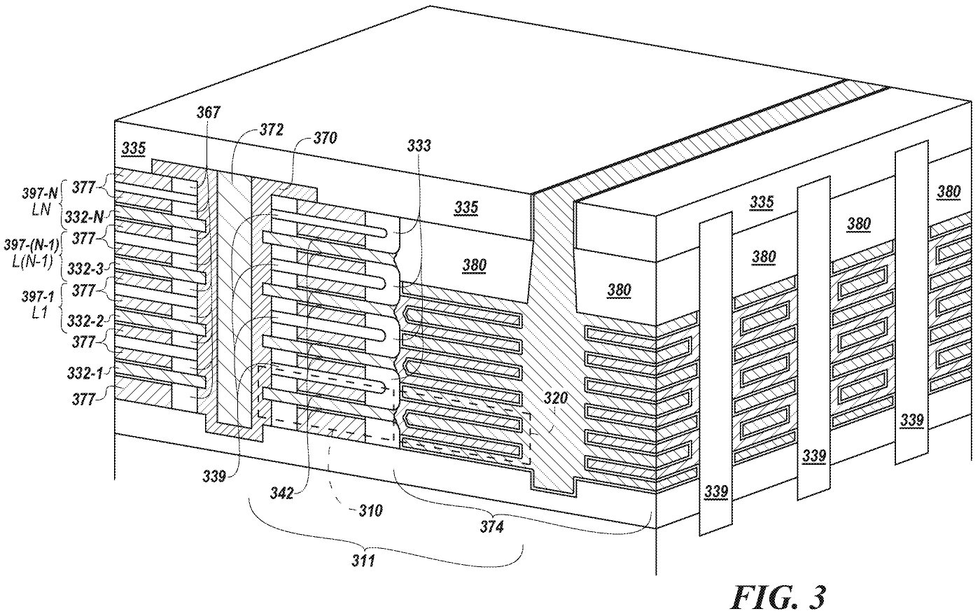

FIG. 3 is a perspective view of a memory device in accordance with a number of embodiments of the present disclosure. FIG. 3 includes a first access device conductive material 377, an Si material 332, a photolithographic mask material (e.g., mask material) 335, an interlayer dielectric (ILD) fill material 367, a second access device conductive material 370, a metal material 372, a first access device dielectric material 339, a second access device dielectric material 333, a second interlayer dielectric material 342, and a plurality of storage nodes (e.g., capacitors) 320.

The 3D memory array can include an array of vertically stacked memory cells 311 having a plurality of levels, such as N levels. FIG. 3 can include level L1 397-1 up to the uppermost levels, levels L(N-1) 397-(N-1) and LN 397-N. The uppermost levels, L(N-1) 397-(N-1) and LN 397-N can include a demultiplexer access device and each level of the plurality of levels below the demultiplexer access device can include memory cells 311 with horizontally oriented access devices 310 and storage nodes 320. In the storage node region 374, the uppermost levels, levels L(N-1) 397-(N-1) and LN 397-N, can include an isolation region 380. Isolation region 380 replaces and prevents storage node 320 from being formed in the uppermost levels, levels L(N-1) 397-(N-1) and LN 397-N, such that the access device 310, the demultiplexer access device, in the uppermost level LN 397-N is not horizontally coupled to a storage node 320 and acts an a demultiplexer access device coupled to a global access line.

Each storage node 320 can include horizontally oriented access devices 310 having first source/drain regions and second source/drain regions separated by channel regions, and gates on a gate dielectric material. The array can further comprise horizontally oriented access lines forming the gates to the horizontally oriented access devices 310. The horizontally oriented access lines can be a gate all around (GAA) structures. The storage nodes 320 can further include horizontally oriented storage nodes 320 electrically coupled to the second source/drain regions of the horizontally oriented access devices 310.

The horizontal access devices 310 of the vertical 3D memory array can include the second access device dielectric material 333, the first access device conductive material 377, a first access device dielectric material 339, and ILD fill material 367. The access devices 310 can be coupled to the plurality of storage nodes 320. In some embodiments, the plurality of storage nodes 320 can be multi-sided capacitors. The access devices 310 can be used to transfer current between the metal material 372 and the plurality of storage nodes 320.

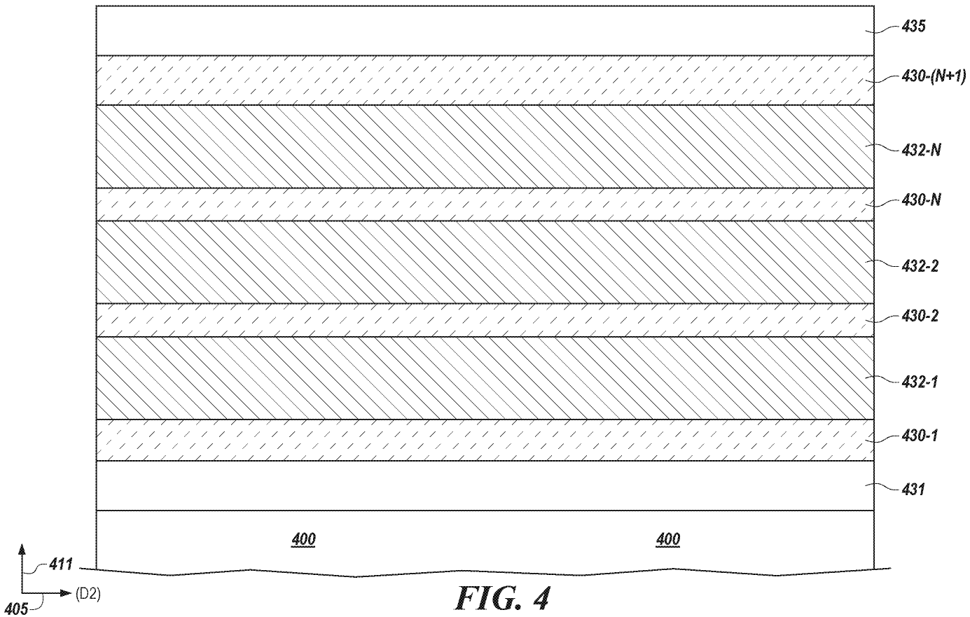

FIG. 4 is a cross-sectional view of a vertical stack in vertical three-dimensional (3D) memory in accordance with a number of embodiments of the present disclosure. In the example embodiment shown in the example of FIG. 4, a method of forming the vertical stack 401 can comprise forming alternating layers of a silicon germanium (SiGe) material, 430-1, 430-2, . . ., 430-N (collectively referred to as silicon germanium (SiGe) 430), and a silicon (Si) material, 432-1, 432-2, . . ., 432-N (collectively referred to as single crystalline silicon (Si) material 432), in repeating iterations to form a vertical stack 401 on a working surface of a semiconductor substrate 400. In some embodiments, the silicon germanium (SiGe) material and the silicon (Si) material can be epitaxially grown.

In one embodiment, the silicon germanium (SiGe) 430 can be deposited to have a thickness, e.g., vertical height in the third direction (D3), in a range of five (5) nanometers to thirty (30) nm. In one embodiment, the silicon (Si) material 432 can be deposited to have a thickness (t2), e.g., vertical height, in a range of thirty (30) nanometers (nm) to sixty (60) nm. Embodiments, however, are not limited to these examples. As shown in FIG. 4, a vertical direction 411 is illustrated as a third direction (D3), e.g., z-direction in an x-y-z coordinate system, analogous to the third direction (D3), among first, second, and third directions, shown in FIGS. 1-3.

In some embodiments, the silicon germanium (SiGe), 430-1, 430-2, . . ., 430-N, may be a mix of silicon and germanium. By way of example, and not by way of limitation, the silicon germanium (SiGe) material 430 may be grown on the substrate material 400. Embodiments are not limited to these examples. In some embodiments, the single crystalline silicon (Si) material, 432-1, 432-2, . . ., 432-N, may comprise a silicon (Si) material in a polycrystalline and/or amorphous state. The single crystalline silicon (Si) material, 432-1, 432-2, . . ., 432-N, may be a low doped, p-type (p-) single crystalline silicon (Si) material. The silicon (Si) material, 432-1, 432-2, . . ., 432-N, may also be formed on the silicon germanium (SiGe) 430. If the silicon germanium (SiGe) 430 was epitaxially grown, the seed is turned to pure silicon after the silicon germanium (SiGe) 430 has been formed.

The repeating iterations of alternating silicon germanium (SiGe), 430-1, 430-2, . . ., 430-N layers and single crystalline silicon (Si) material, 432-1, 432-2, . . ., 432-N layers may be deposited according to a semiconductor fabrication process such as chemical vapor deposition (CVD) in a semiconductor fabrication apparatus. Embodiments, however, are not limited to this example and other suitable semiconductor fabrication techniques may be used to deposit the alternating layers of silicon germanium (SiGe) and single crystalline silicon (Si) material, in repeating iterations to form the vertical stack 401.

The layers may occur in repeating iterations vertically. For example, the stack may include: a first silicon germanium (SiGe) material 430-1, a first single crystalline silicon (Si) material 432-1, a silicon germanium (SiGe) material 430-2, a second single crystalline silicon (Si) material 432-2, a third silicon germanium (SiGe) material 430-3, and a third single crystalline silicon (Si) material 432-3, in further repeating iterations. Embodiments, however, are not limited to this example and more or fewer repeating iterations may be included.

In some embodiments, a bottom portion of the vertical stack 401 can be removed to form a horizontal opening. The bottom portion of the vertical stack 401 can include a layer of silicon germanium (SiGe) material 430 that is closer to the substrate 400 than other layers of silicon germanium (SiGe) material 430, a layer of silicon (Si) material 432 that is closer to the substrate 400 than other layers of silicon (Si) material 432, or both. Further, a fill dielectric material 431 can be deposited to fill the horizontal opening.

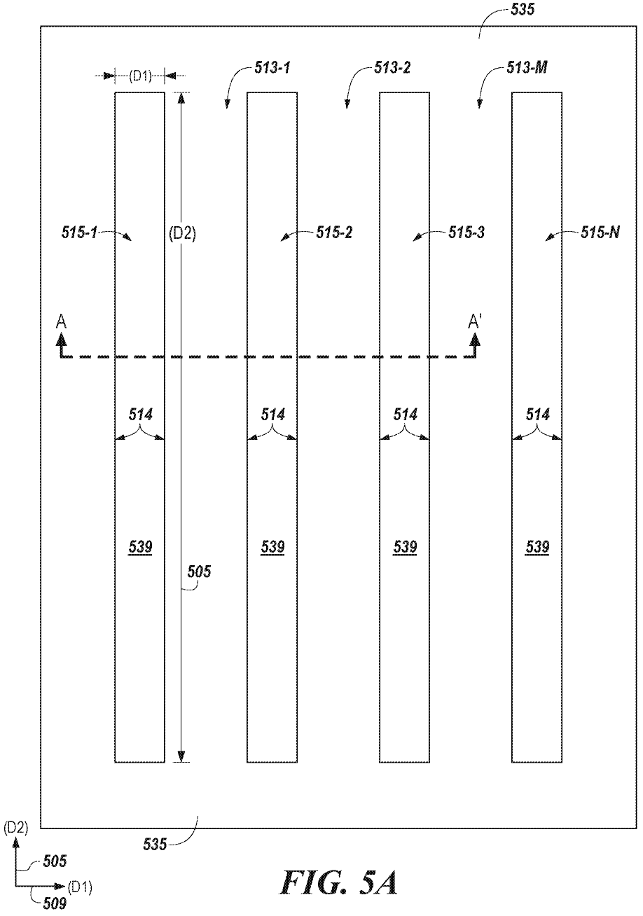

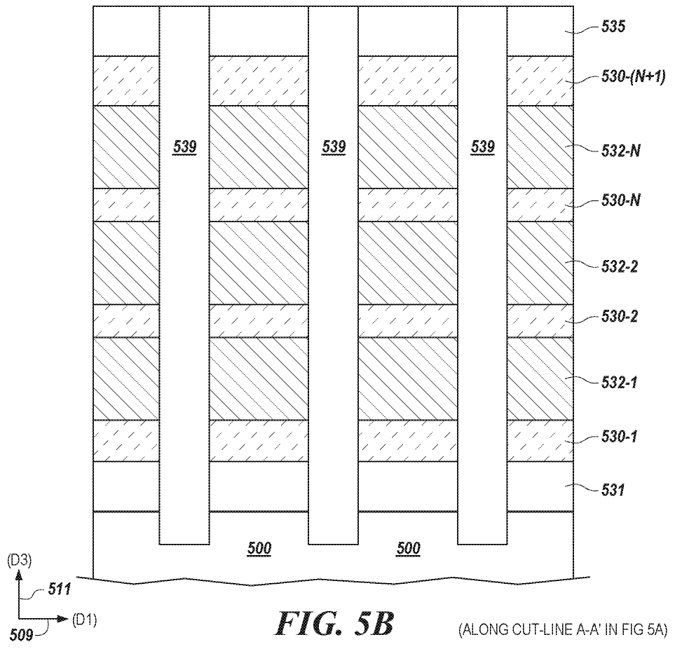

FIG. 5A illustrates an example method, at one stage of a semiconductor fabrication process, for forming multi-sided storage nodes in vertical 3D memory, in accordance with a number of embodiments of the present disclosure. FIG. 5A illustrates a top down view of a semiconductor structure, at a particular point in time, in a semiconductor fabrication process, according to one or more embodiments. In the example embodiment shown in the example of FIG. 5A, the method comprises using an etchant process to form a plurality of vertical openings 515-1, 515-2, 515-3, . . ., 515-N (individually or collectively referred to as vertical openings 515), having a first horizontal direction (D1) 509 and a second horizontal direction (D2) 505, through the vertical stack to the substrate. In one example, as shown in FIG. 5A, the plurality of vertical openings 515 are extending predominantly in the second horizontal direction (D2) 505 and may form elongated vertical, columns 513-1, 513-2, . . ., 513-M (collectively and/or independently referred to as vertical columns 513), with sidewalls 514 in the vertical stack. The plurality of first vertical openings 515 may be formed using photolithographic techniques to pattern a photolithographic mask 535, e.g., to form a hard mask (HM), on the vertical stack prior to etching the plurality of first vertical openings 515. Similar semiconductor process techniques may be used at other points of the semiconductor fabrication process described herein.

The vertical openings 515 may be filled with a first access device dielectric material 539. In one example, a spin on dielectric process may be used to fill the first vertical openings 515. In one embodiment, the first access device dielectric material 539 may be an oxide material. However, embodiments are not so limited.

FIG. 5B is a cross-sectional view, taken along cut-line A-A’ in FIG. 5A, showing another view of the semiconductor structure at a particular time in the semiconductor fabrication process for forming multi-sided storage nodes in vertical 3D memory, in accordance with a number of embodiments of the present disclosure. The cross-sectional view shown in FIG. 5B shows the repeating iterations of alternating layers of a silicon germanium (SiGe) material 530 and a single crystalline silicon (Si) material 532 on a semiconductor substrate 500 to form the vertical stack, e.g., vertical stack 501 in FIG. 4.

As shown in FIG. 5B, a plurality of vertical openings may be formed through the layers within the vertically stacked memory cells to expose vertical sidewalls in the vertical stack and form elongated vertical pillar columns 513 and then filled with a first dielectric material 539. The vertical openings 515 may be formed through the repeating iterations of the silicon germanium (SiGe) material 530 and the single crystalline silicon (Si) material 532. As such, the vertical openings 515 may be formed through a first silicon germanium (SiGe) material 530-1, a first single crystalline silicon (Si) material 532-1, a second silicon germanium (SiGe) material 530-2, a second single crystalline silicon (Si) material 532-2, a third silicon germanium (SiGe) material 530-3, and a third single crystalline silicon (Si) material 532-3. Embodiments, however, are not limited to the vertical opening(s) shown in FIG. 5B. Multiple vertical openings may be formed through the layers of materials. The vertical openings may be formed to expose vertical sidewalls in the vertical stack. The vertical openings may extend in a second direction (D2) 505 to form elongated vertical columns with vertical sidewalls in the vertical stack and then filled with first access device dielectric material 539.

As shown in FIG. 5B, a first dielectric material 539, such as an oxide or other suitable spin on dielectric (SOD), may be deposited in the vertical openings 515, using a process such as CVD, to fill the vertical openings 515. First access device dielectric material 539 may also be formed from a silicon nitride (Si₃N₄) material. In another example, the first access device dielectric material 539 may include silicon oxy-nitride (SiOₓN_{y}), and/or combinations thereof. Embodiments are not limited to these examples. The plurality of vertical openings 515 may be formed using photolithographic techniques to pattern a photolithographic mask 535, e.g., to form a hard mask (HM), on the vertical stack prior to etching the plurality of first vertical openings 515. In one embodiment, hard mask 535 may be deposited over a silicon germanium (SiGe) material 530. Similar semiconductor process techniques may be used at other points of the semiconductor fabrication process described herein.

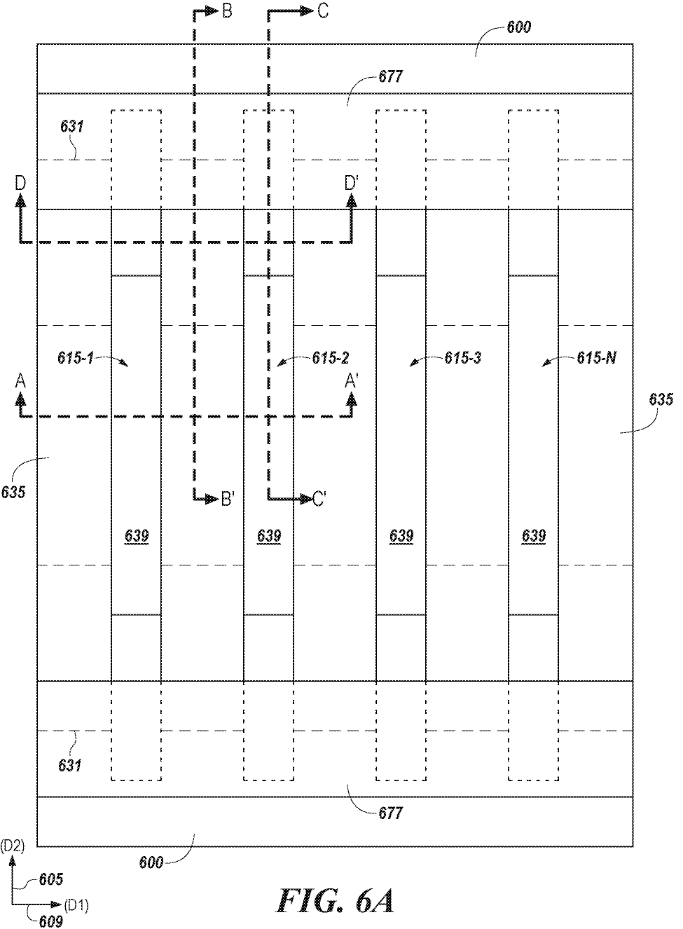

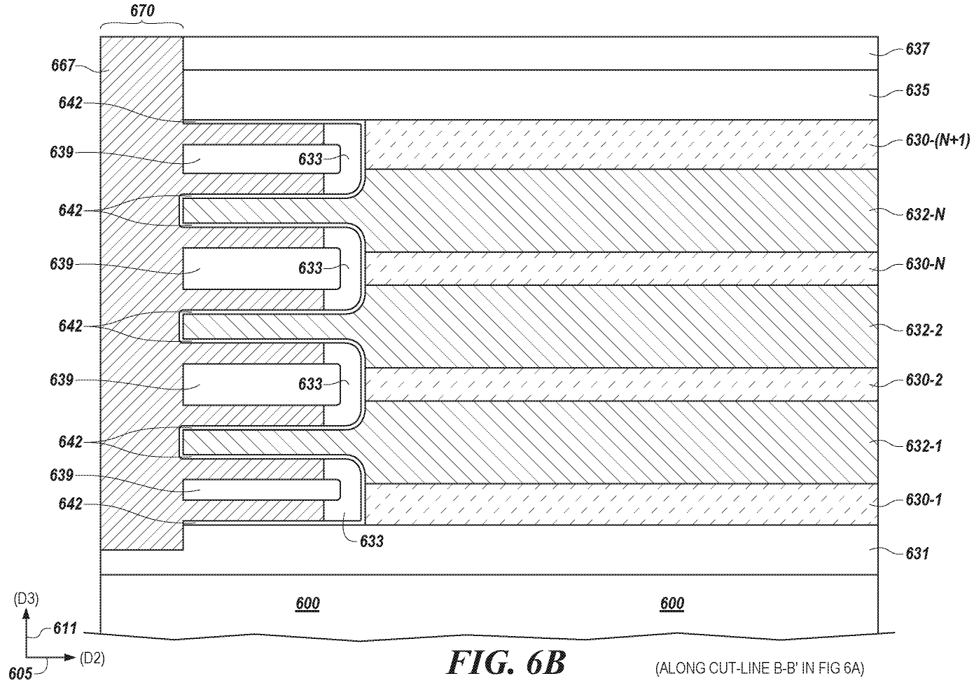

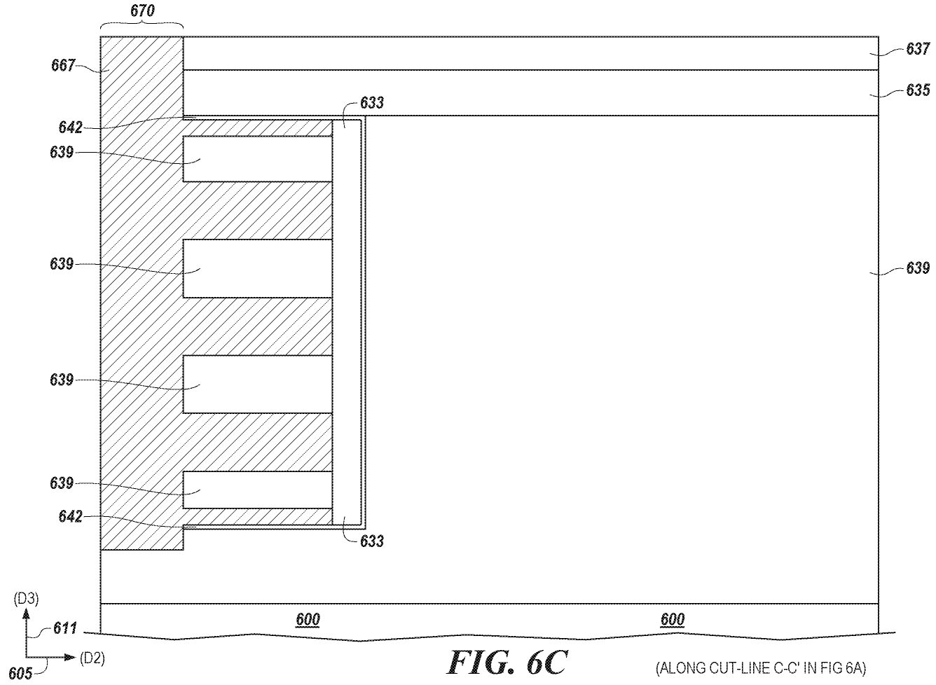

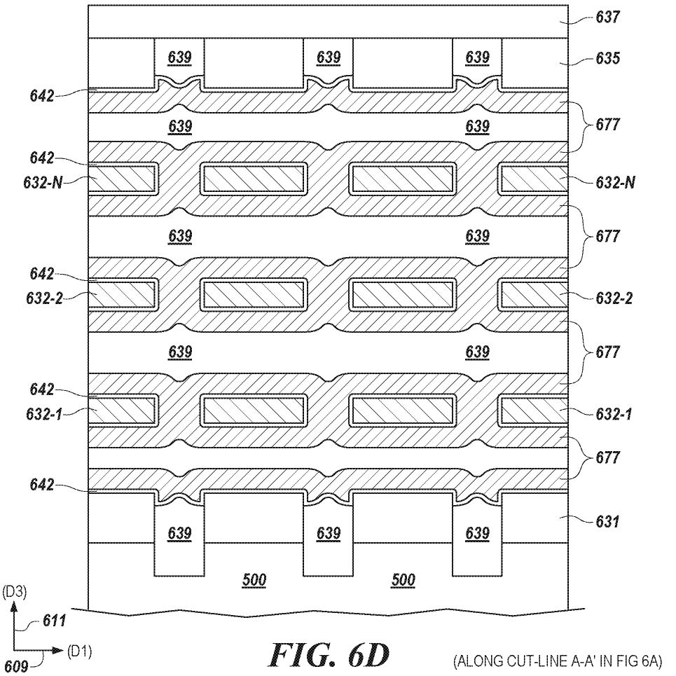

FIG. 6A illustrates an example method, at another stage of a semiconductor fabrication process for forming multi-sided storage nodes in vertical 3D memory, in accordance with a number of embodiments of the present disclosure. FIG. 6A illustrates a top down view of a semiconductor structure, at a particular point in time, in a semiconductor fabrication process, according to one or more embodiments. In the example embodiment of FIG. 6A, the method comprises using a photolithographic process to pattern the photolithographic mask 635. A first access device conductive material 677 may be deposited above the vertical openings 631. The first access device conductive material 677 may be deposited in the continuous first horizontal openings to form horizontally oriented access lines opposing channel regions of the single crystalline silicon (Si) material 632.

FIG. 6B illustrates a cross sectional view, taken along cut-line B-B’ in FIG. 6A, showing another view of the semiconductor structure at this particular point in one example semiconductor fabrication process for forming multi-sided storage nodes in vertical 3D memory, in accordance with a number of embodiments of the present disclosure. The cross-sectional view shown in FIG. 6B is illustrated extending in the second horizontal direction (D2) 605, left and right along the plane of the drawing sheet, along an axis of the repeating iterations of alternating layers of the silicon germanium (SiGe) material 630 and the single crystalline silicon (Si) material 632.

A process of depositing and etching materials is used to form the structure shown in FIG. 6B. In some embodiments, the process of depositing and etching materials can include forming horizontally oriented access devices and horizontally oriented storage nodes (e.g., storage nodes 227 in FIG. 2) at each level of the vertical stack (e.g., vertical stack 401 in FIG. 4) to form an array of vertically stacked memory cells. Each of the horizontally oriented access devices can have first source/drain regions and second source/drain regions separated by channel regions. In some embodiments, gates can be formed fully around every surface of the channel regions as gate all around (GAA) structures on a gate dielectric material. Further, in some embodiments, the second source/drain regions can be coupled to storage nodes.

The semiconductor structure shown in FIG. 6B shows the semiconductor structure after the silicon germanium (SiGe) layers are selectively etched to form a plurality of horizontal openings a first length from the vertical openings 670. In some embodiments, the vertical openings 670 can be formed to a depth in a range of 0.5 to one (1) micrometer (µm). Further, in some embodiments, each of the vertical openings 670 can be formed to have an aspect ratio in a range of 15-20. In some embodiments, the selective etch that forms to plurality of second horizontal openings can also reduce a vertical thickness of the silicon (Si) layers. In some embodiments, a vertical thickness of a portion of each of the silicon (Si) layers can be reduced to a vertical thickness in a range of 100-150 Angstroms (Å).

The process of forming the horizontally oriented access devices can further include conformally depositing a second access device dielectric material 633 on exposed surfaces in the plurality of horizontal openings and depositing the first access device dielectric material 639 to fill the plurality of horizontal openings. The second access device dielectric material 639 can be selectively etched from the plurality of first horizontal openings a second length (L2) from the vertical opening 670. In some embodiments, the second length (L2) can be a length in a range of 130-170 nanometers (nm).

A first access device conductive material 677 may be deposited in the horizontal opening on the gate dielectric material 642 after selectively etching the second access device dielectric material 639. The first access device conductive material 677 may be deposited around the single crystalline silicon (Si) material 632 such that the first access device conductive material 677 may have a top portion above the single crystalline silicon (Si) material 632 and a bottom portion below the single crystalline silicon (Si) material to form a gate all around (GAA) gate structure, at a channel of an access device region. The first access device conductive material 677 may be conformally deposited into vertical openings 670 and fill the continuous horizontal openings up to the unetched portions of the oxide material 642, the first access device dielectric material 639, and the dielectric material 633. The conductive material 677 may be conformally deposited using a chemical vapor deposition (CVD) process, plasma enhanced CVD (PECVD), atomic layer deposition (ALD), or other suitable deposition process.

In some embodiments, the first access device conductive material 677, may comprise one or more of a doped semiconductor, e.g., doped silicon, doped germanium, etc., a conductive metal nitride, e.g., titanium nitride, tantalum nitride, etc., a metal, e.g., tungsten (W), titanium (Ti), tantalum (Ta), ruthenium (Ru), cobalt (Co), molybdenum (Mo), etc., and/or a metal-semiconductor compound, e.g., tungsten silicide, cobalt silicide, titanium silicide, etc., and/or some other combination thereof. The first access device conductive material 677 entwined with the gate dielectric material may form horizontally oriented access lines opposing a channel region of the single crystalline silicon (Si) material (which also may be referred to a word lines).

FIG. 6C illustrates a cross sectional view, taken along cut-line C-C’ in FIG. 6A, showing another view of the semiconductor structure at this particular point in one ex ample semiconductor fabrication process of an embodiment of the present disclosure. The cross sectional view shown in FIG. 6C is illustrated extending in the second horizontal direction (D2) 605, left and right in the plane of the drawing sheet, along an axis of the repeating iterations of alternating layers of continuous horizontal openings and single crystalline silicon (Si) material 632.

In FIG. 6C, first dielectric material 639 is shown spaced along a second horizontal direction (D2) 605, extending into and out from the plane of the drawings sheet, for a three-dimensional (3D) array of vertically oriented memory cells. At the left end of the drawing sheet is shown the repeating iterations of alternating layers of single crystalline silicon (Si) material 632, separated by continuous horizontal openings in a first direction (D1) 609 filled with a first conductive material 677. The first access device conductive material 677 may be conformally deposited into vertical openings 670 and into the horizontal openings. The first access device conductive material 677 is formed on the gate dielectric material (e.g., gate dielectric material 642 in FIG. 6B). At the right hand of the drawing sheet, the first access device dielectric material 639 may be seen, separating access device and storage node regions in the first direction (D1) 609, and having the horizontal opening filled with the second access device dielectric material 633 and the first access device dielectric material 639.

FIG. 6D illustrates a cross sectional view, taken along cut-line D-D’ in FIG. 6A, showing another view of the semiconductor structure at this particular point in one example semiconductor fabrication process for forming multi-sided storage nodes in vertical 3D memory, in accordance with a number of embodiments of the present disclosure. The cross sectional view shown in FIG. 6D is illustrated, right to left in the plane of the drawing sheet, extending in the first direction (D1) 609 along an axis of the repeating iterations of alternating layers of first dielectric material 639 and single crystalline silicon (Si) material 632 wrapped with a gate dielectric material 642. The gate dielectric material 642 may be conformally deposited fully around every surface of the single crystalline silicon (Si) material 632, to form gate all around (GAA) gate structures, at the channels of the access device regions. The first access device conductive material 677 may fill the spaces adjacent the bridged single crystalline silicon (Si) material 632. The single crystalline silicon (Si) material 632 may be surrounded by the first access device conductive material 677 formed on the gate dielectric material 642. The first conductive material 677 may be conformally deposited fully around every surface of the single crystalline silicon (Si) material 632, to form gate all around (GAA) gate structures, at the channels of the access device regions. In FIG. 6D, the first access device conductive material, 677 is shown filling in the space in the second horizontal openings left by the etched dielectric material 633.

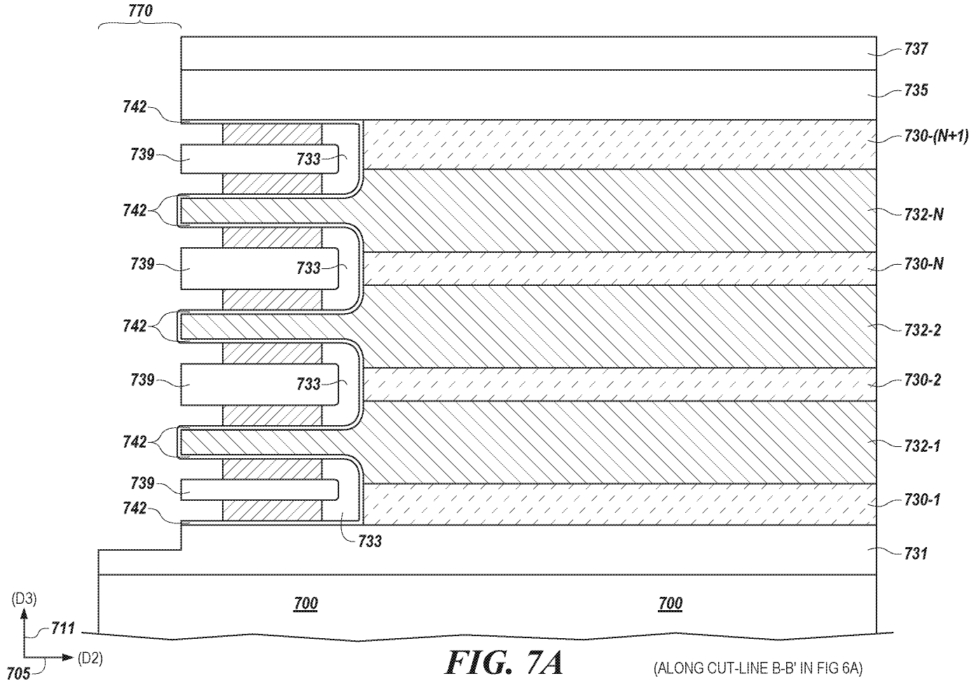

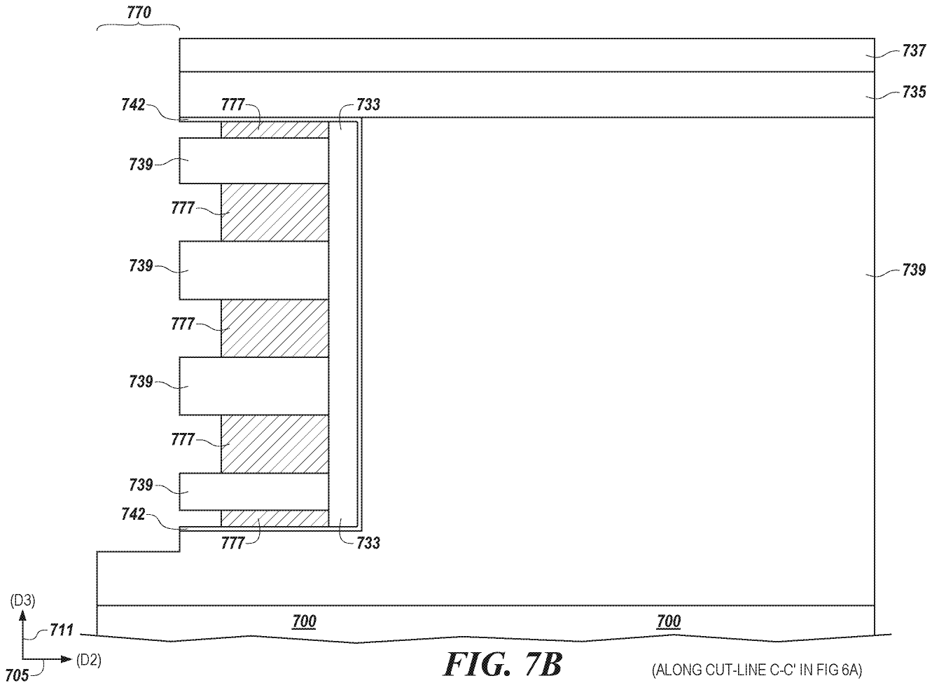

FIG. 7A illustrates an example method, at another stage of a semiconductor fabrication process, for forming multi-sided storage nodes in vertical 3D memory, in accordance with a number of embodiments of the present disclosure. The cross-sectional view shown in FIG. 7A is illustrated extending in the second horizontal direction (D2) 705, left and right along the plane of the drawing sheet, along an axis of the repeating iterations of alternating layers of the silicon germanium (SiGe) material 730 and the single crystalline silicon (Si) material 732.

A first access device conductive material 777 was deposited on the gate dielectric material and formed around the single crystalline silicon (Si) material 732, recessed back, to form gate all around (GAA) structure opposing channel regions of the single crystalline silicon (Si) material 732. The first access device conductive material 777, formed on the gate dielectric material 742, may be recessed and etched away from the vertical opening 770. In some embodiments, the first access device conductive material 777 may be etched using an atomic layer etching (ALE) process. In some embodiments, the first access device conductive material 777 may be etched using an isotropic etch process. The first access device conductive material 777 may be selectively etched leaving the oxide material 742 covering the epitaxially grown, single crystalline silicon (Si) material 732 and the first access device dielectric material 739 intact. The first access device conductive material 777 may be selectively etched in the second direction, in the continuous horizontal openings, a third distance (DIST 3) in a range of twenty (20) to fifty (50) nanometers (nm) back from the first vertical opening 770. The first access device conductive material 777 may be selectively etched around the single crystalline silicon (Si) material 732 back into the continuous horizontal openings extending in the first horizontal direction.

FIG. 7B illustrates an example method, at another stage of a semiconductor fabrication process, for forming multi-sided storage nodes in vertical 3D memory, in accordance with a number of embodiments of the present disclosure. The cross-sectional view shown in FIG. 7B is illustrated extending in the second direction (D2) 705, left and right in the plane of the drawing sheet, along an axis of the repeating iterations of alternating layers of the etched first access device conductive material 777 and single crystalline silicon (Si) material 732.

In FIG. 7B, first access device dielectric material 739 is shown spaced along a first horizontal direction (D1) 709 extending into and out from the plane of the drawings sheet, for a three-dimensional (3D) array of vertically oriented memory cells. At the left end of the drawing sheet is shown the first access device conductive material 777 formed on the gate dielectric material 742, was etched away from the vertical opening 770. The first access device conductive material 777, formed on the gate dielectric material 742, is also recessed back in the continuous horizontal openings extending in the first horizontal direction 709. The first access device conductive material 777 may be selectively etched leaving the oxide material 742 covering the single crystalline silicon (Si) material 732 intact. In some embodiments, the first access device conductive material 777 may be etched using an atomic layer etching (ALE) process. In some embodiments, the first access device conductive material 777 may be etched using an isotropic etch process.

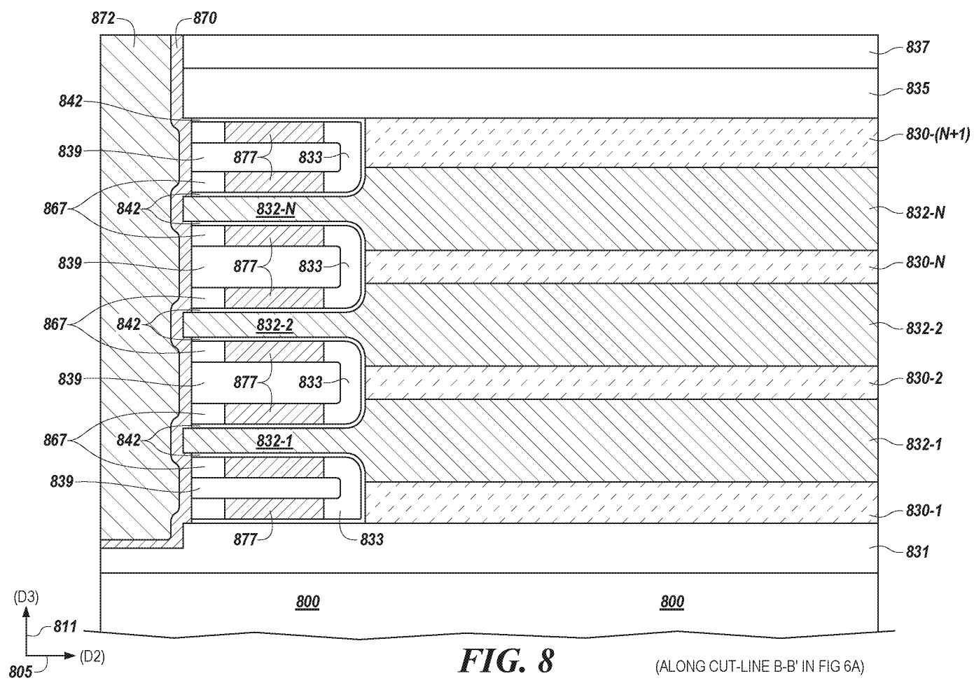

FIG. 8 illustrates an example method, at another stage of a semiconductor fabrication process, for forming multi-sided storage nodes in vertical 3D memory, in accordance with a number of embodiments of the present disclosure. The cross-sectional view shown in FIG. 8 is illustrated extending in the second horizontal direction (D2) 805, left and right along the plane of the drawing sheet.

FIG. 8 illustrates an example embodiment of a vertical digit line formed by the combination of second access device conductive material 870 and second digit line conductive material 872 formed within the vertical openings (e.g., vertical openings 770 in FIG. 7). In one example, a first digit line conductive material 870 may be conformally formed in the vertical openings. The first digit line conductive material 870 may be formed from a conformal deposition of a highly doped polysilicon material 870. In one example, the dopant can include a high concentration n-type dopant. In a further example, the polysilicon may first be deposited and then a high concentration of n-type dopant may be implanted therein from the first digit line conductive material 870. One example of forming the first digit line conductive material 870 includes conformally depositing a highly phosphorus (P) doped (n+-type dopant) poly-silicon germanium (SiGe) material into the first vertical openings for the second conductive material 870.

A second digitline conductive material 872 may be deposited into the vertical opening on the first digitline conductive material 870 to fill the vertical opening as shown in FIG. 8. In some embodiments, the second digit line conductive material 872 may comprise one or more of a doped semiconductor material, e.g., doped silicon, doped germanium, etc., a conductive metal nitride, e.g., titanium nitride, tantalum nitride, etc., a metal, e.g., tungsten (W), titanium (Ti), tantalum (Ta), ruthenium (Ru), cobalt (Co), molybdenum (Mo), etc., and/or a metal-semiconductor compound, e.g., tungsten silicide, cobalt silicide, titanium silicide, etc., and/or some other combination thereof. The second digit line conductive material 872 formed on the first digit line conductive material 870 may be formed vertically adjacent first source/drain regions to horizontal access devices to form vertical digit lines.

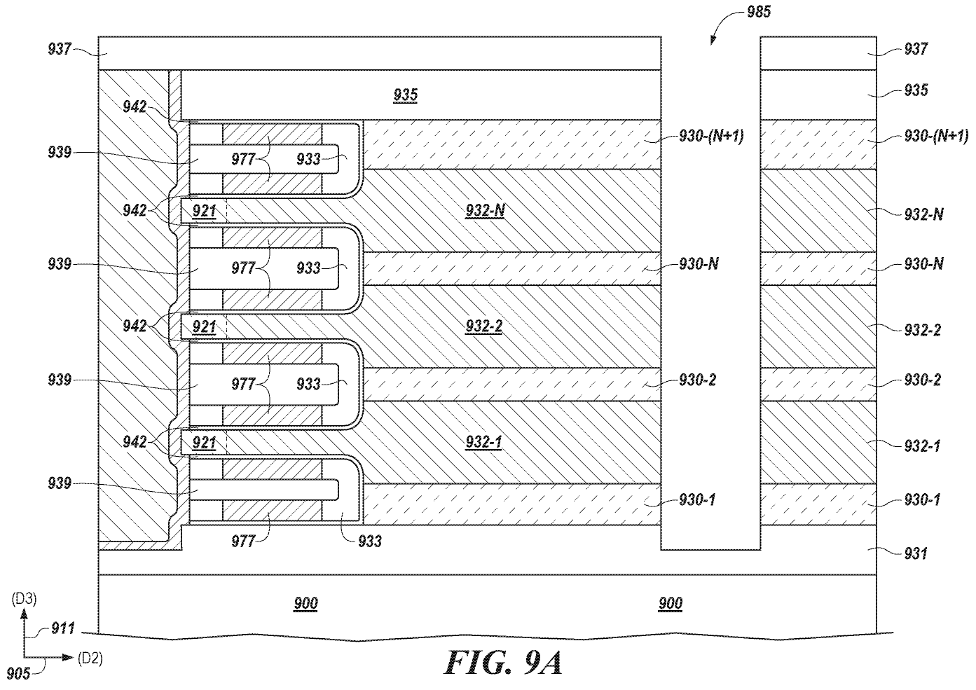

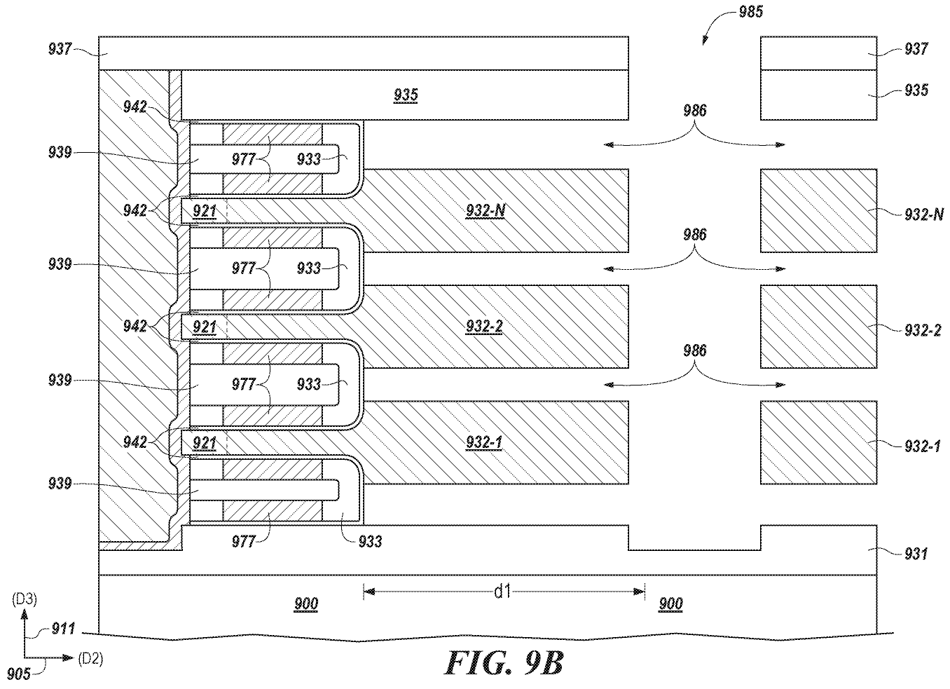

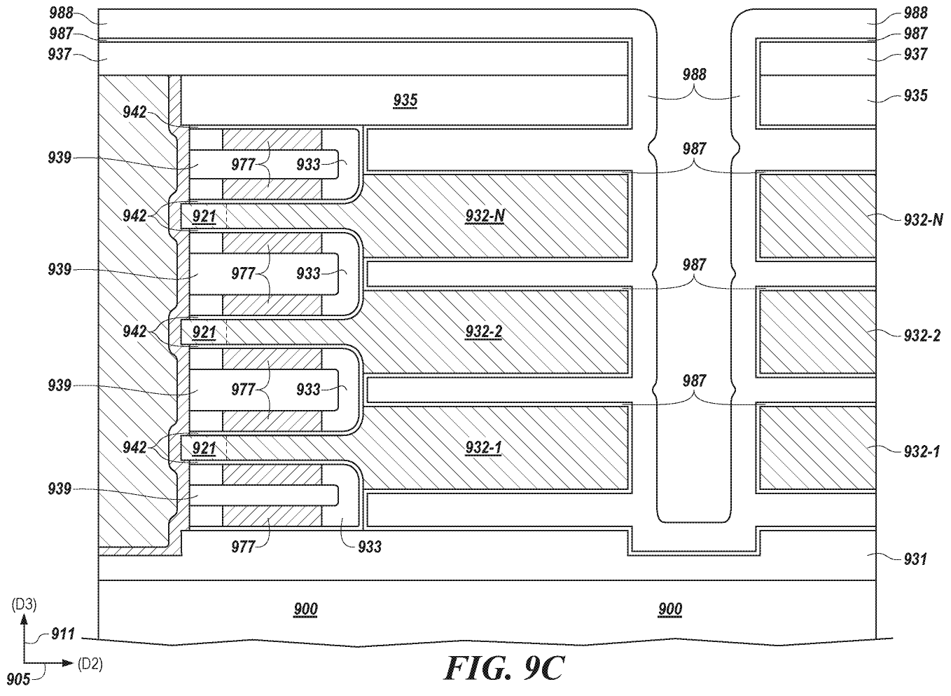

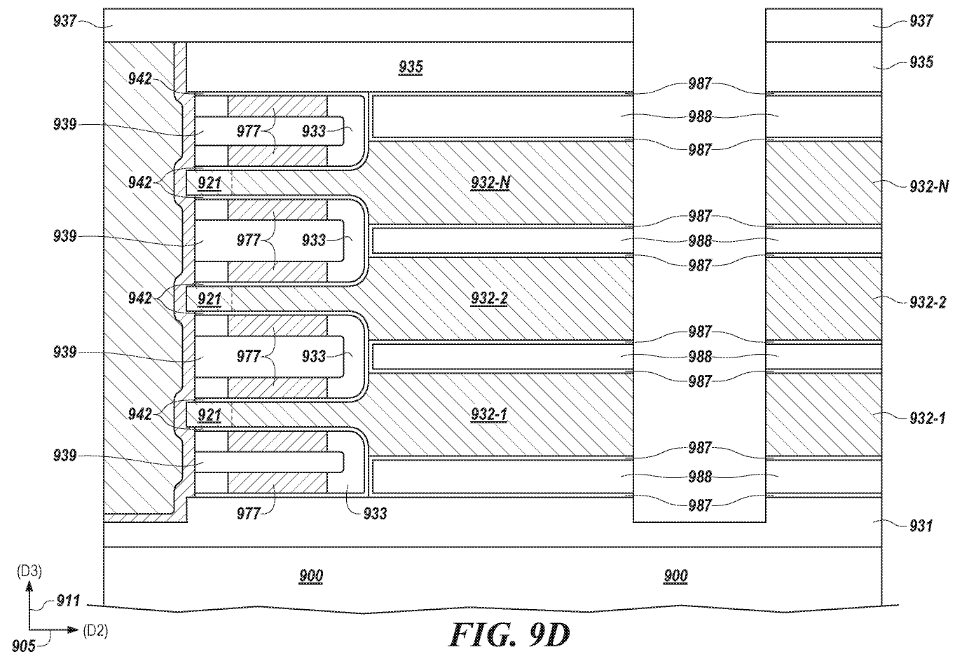

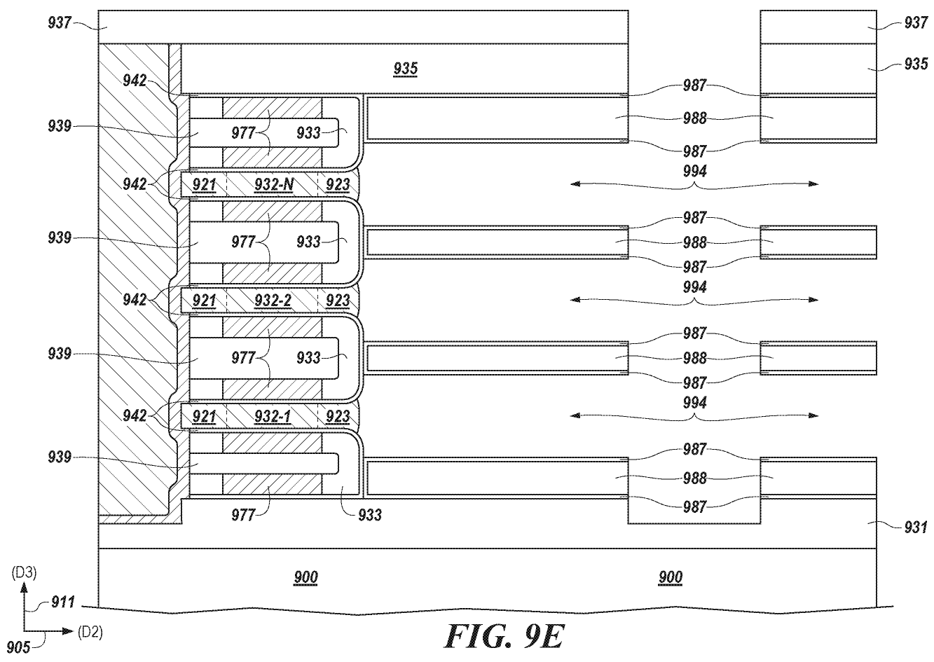

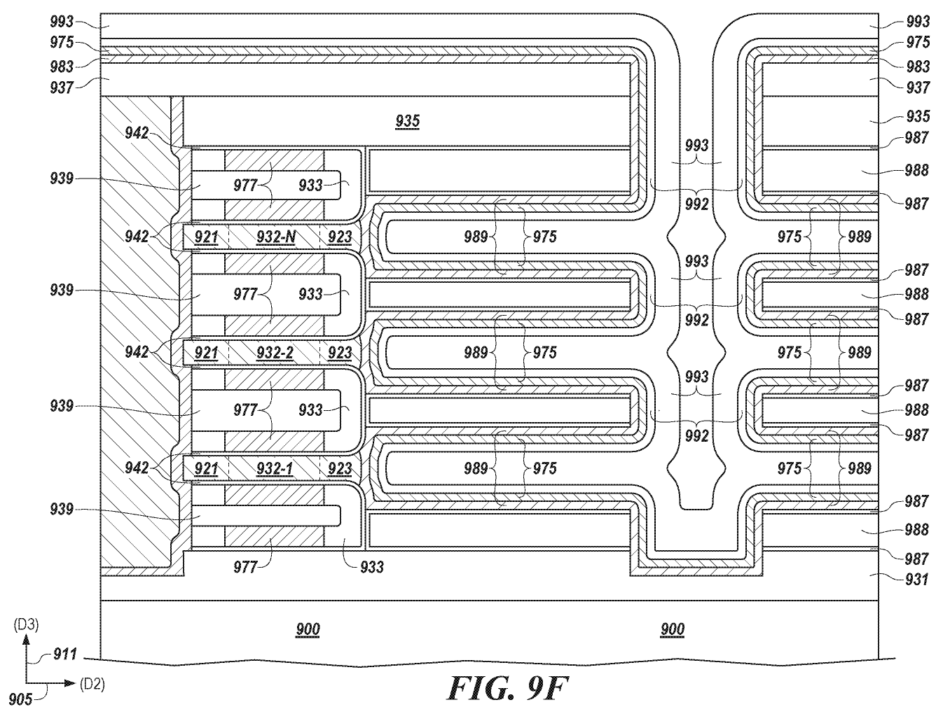

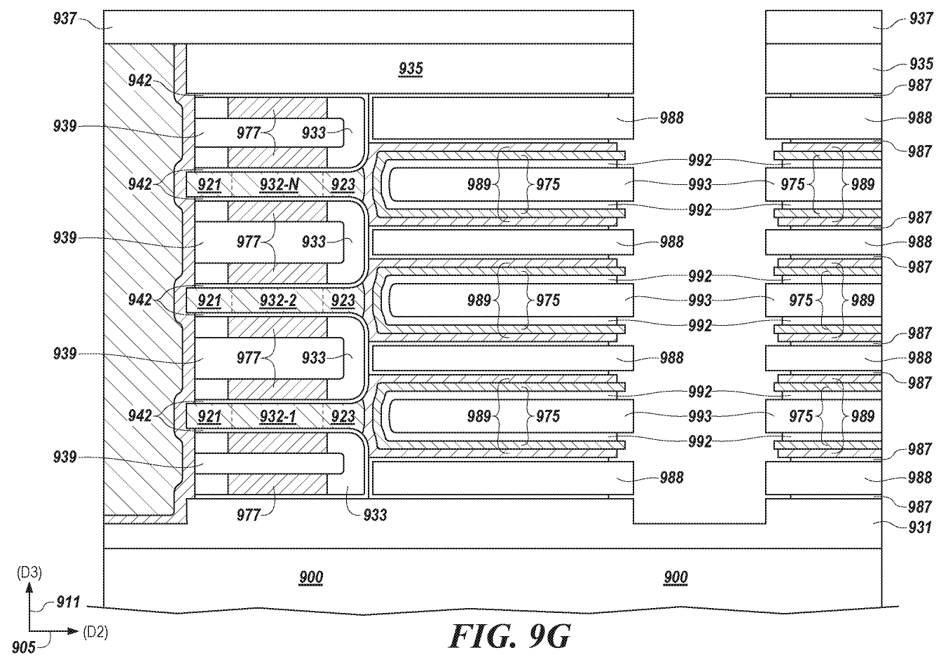

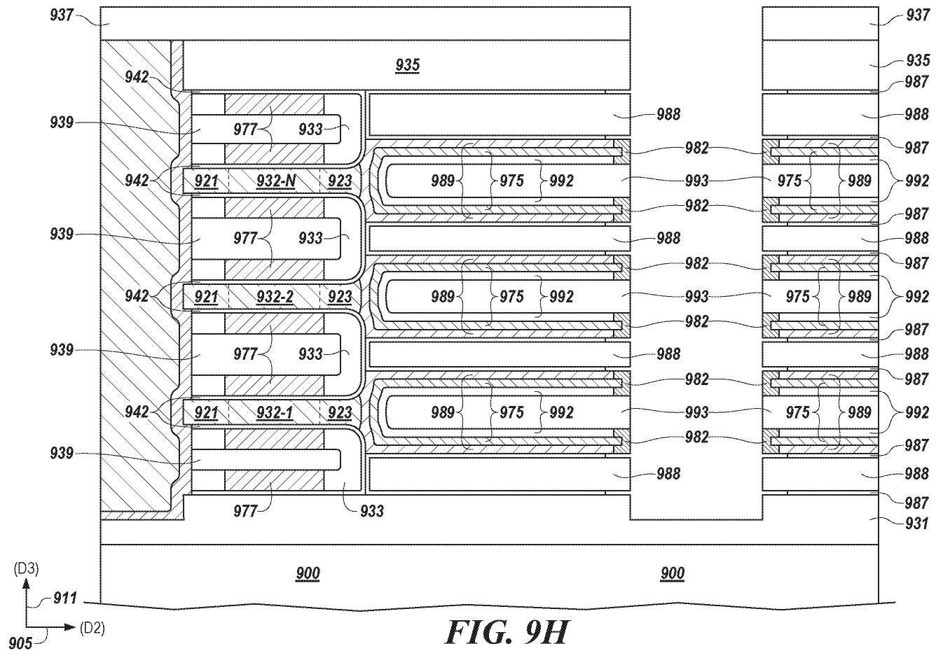

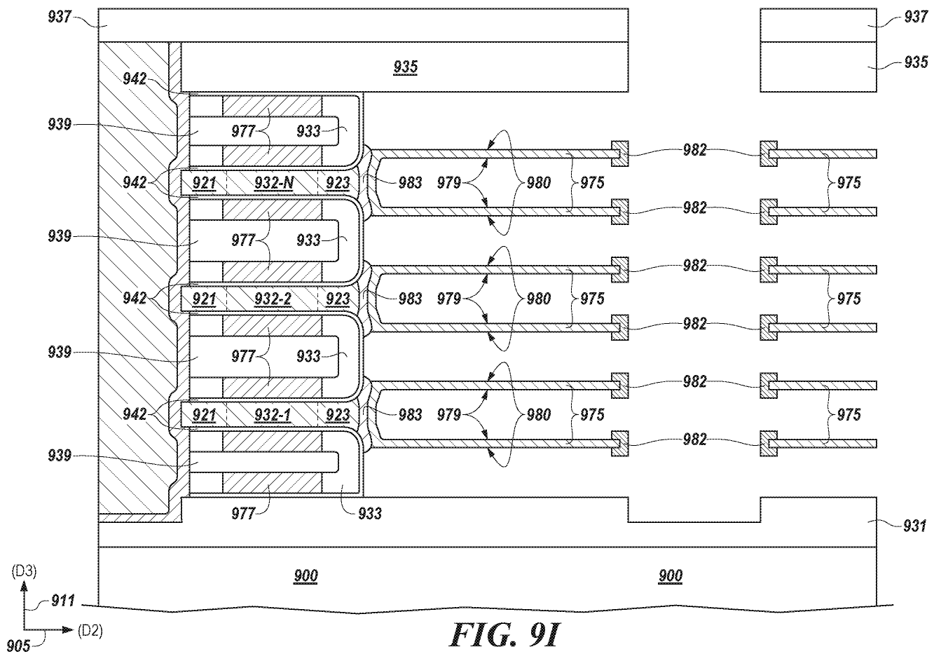

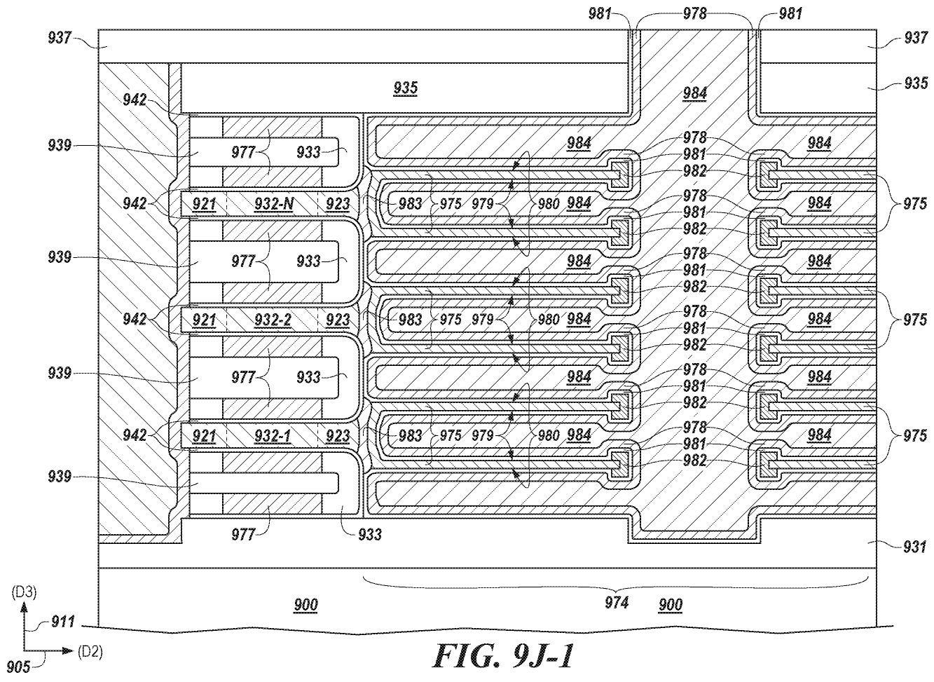

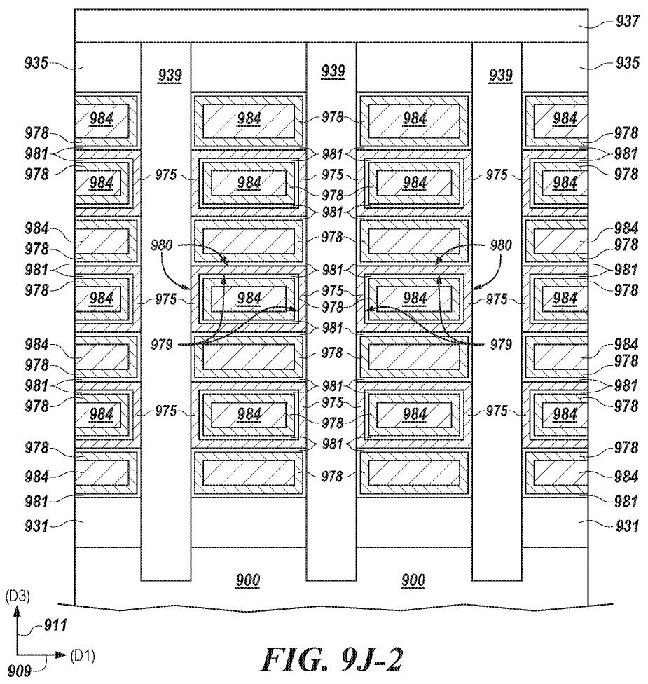

FIGS. 9A to 9J illustrate an example method for forming extended multi-sided storage nodes in vertical 3D memory, in accordance with a number of embodiments of the present disclosure. For example, FIG. 9A to 9J can illustrate stages of forming the extended multi-sided storage node illustrated in FIG. 9J.

FIG. 9A illustrates an example method, at one stage of a semiconductor fabrication process, for forming extended multi-sided storage nodes in vertical 3D memory, in accordance with a number of embodiments of the present disclosure. The stage illustrated in the example shown in FIG. 9A can follow the stage previously described in connection with FIG. 8, for instance. As shown in FIG. 9A, a vertical opening 985 can be formed through a vertical stack of alternating layers of silicon germanium (SiGe) material 930 and silicon (Si) material 932 and adjacent to storage node regions for the vertical memory cells.

FIG. 9B illustrates an example method, at one stage of a semiconductor fabrication process, for forming extended multi-sided storage nodes in vertical 3D memory, in accordance with a number of embodiments of the present disclosure. As shown in FIG. 9B, SiGe material 930 can be removed via the vertical opening 985 to form first horizontal openings 986. In some embodiments, the SiGe material 930 is removed entirely forming the first horizontal openings 986 a first distance (d1) from the vertical opening 985. The SiGe material 930 can be removed by an etching process, such as a hydrofluoric acid and/or a Bryce vapor etch process, for instance. In some embodiments, removing the SiGe 930 material additionally removes a portion of the Si material 932 in the third direction (D3), e.g., vertical direction, resulting in a reduced vertical thickness (vt) (e.g., thinned) Si material 932, which can further expand the first horizontal openings 986 in a vertical direction to have an increased vertical height (vh). In some embodiments, the Si material 932 can be thinned by a vertical distance in a range of 4-5 nanometers (nm). Further, in some embodiments, the Si material 932 can be removed from each of the Si layers such that each of the resultant Si layers has a thickness in a range of 70 to 65nm in the vertical direction. Si material 932 can be removed using an ammonia-peroxide mixture (APM and/or SC1), for instance.

FIG. 9C illustrates an example method, at one stage of a semiconductor fabrication process, for forming extended multi-sided storage nodes in vertical 3D memory, in accordance with a number of embodiments of the present disclosure. As shown in FIG. 9C, a first dielectric material (e.g., an oxide material (SiO2)) 987, is formed in the first horizontal openings 986. In some embodiments, forming the first dielectric material 987 in the first horizontal openings 986 can include conformally depositing an oxide material 987 on exposed surfaces in the first horizontal openings 986. In some embodiments, conformally depositing the oxide material 987 can include using an atomic layer deposition (ALD) technique to deposit the first dielectric material 987 on the exposed surfaces in the first horizontal openings 986. Some embodiments can include forming the first dielectric material 987 to a thickness of between 1.5 and 2.5nm. As further illustrated in FIG. 9C a second dielectric material 988 can be formed in the first horizontal openings 986 to fill the first horizontal openings 986 and conformally cover a portion of exposed surface in the vertical opening 985. In some embodiments, the second dielectric material can include a nitride material (e.g., Si₃N₄).

FIG. 9D illustrates an example method, at one stage of a semiconductor fabrication process, for forming extended multi-sided storage nodes in vertical 3D memory, in accordance with a number of embodiments of the present disclosure. As shown in FIG. 9D, the first and the second dielectric materials 987 and 988 are removed from the vertical opening 985 to expose the alternating layers of Si material 932 to the vertical opening 985. The first dielectric material 987 and the second dielectric material 988 can be removed by a gas etch process, in some embodiments.

FIG. 9E illustrates an example method, at one stage of a semiconductor fabrication process, for forming extended multi-sided storage nodes in vertical 3D memory, in accordance with a number of embodiments of the present disclosure. As shown in FIG. 9G, the Si material 932 can be removed to form second horizontal openings 994. The Si material 932 may be removed to form second horizontal openings 994 to have a distance (d1) from the first vertical opening 985 that is equivalent to a distance (d1) of the first horizontal openings 986. Second source/drain regions 923 can be formed by gas phase doping, e.g., using phosphorus (P), the exposed Si material 932 interior at an end of the second horizontal openings 994. Removing the Si material 932 can be carried out by a gas etch process, followed by an O₂/NH₃ strip process, followed by a diluted hydrofluoric acid (e.g., diluted 300:1) and Selis^{TM} vapor etch process, for instance.

FIG. 9F illustrates an example method, at one stage of a semiconductor fabrication process, for forming extended multi-sided storage nodes in vertical 3D memory, in accordance with a number of embodiments of the present disclosure. As illustrated in FIG. 9F, embodiments herein include depositing a polysilicon material 989 interior to the second horizontal openings 994 on the first dielectric material 987 and the second source/drain regions 923. In some embodiments, the polysilicon 989 material can be annealed after deposition such that dopants from the second source/drain region 923 can migrate into polysilicon material 989 to form a doped silicon interface material (e.g., doped polysilicon material) 983. In some embodiments, the doped silicon material 983 can be doped in a dosage exceeding 1e21 of phosphorus (P) per cubic centimeter. In some embodiments, the polysilicon material 989 can be formed to a thickness in a range of 5-15nm by a chemical vapor deposition (CVD) process. Further, in some embodiments, this CVD process can be followed by a rapid thermal processing stage with a spike of 1050 Celsius (C) to form the doped silicon material 983, though embodiments herein are not so limited.

As further illustrated in FIG. 9F, a first conductive material (e.g., titanium nitride (TiN)) 975, to serve as a first electrode, can be formed interior to the second horizontal openings 994 on exposed polysilicon surfaces 989 and on the doped silicon material 983. In some embodiments, the first conductive material 975 can be titanium nitride (TiN). In other embodiments, the first conductive material 975 can include titanium nitride (TiN) and titanium silicon oxynitride (TiSiON). In some embodiments, the first conductive material 975 can be formed to a thickness in a range of 3-9nm using a CVD process at approximately 475 degrees C.

As further illustrated in FIG. 9F, a third dielectric material 992 can be formed on the first conductive material, e.g., first electrode 975. In some embodiments, the third dielectric material 992 can be an oxide material (e.g., silicon dioxide (SiO₂)). The third dielectric material 992 can be formed to a thickness in a range of between 1-3nm using a PEALD process (e.g., XP8®).

As further illustrated in FIG. 9F, a fourth dielectric material 993 is formed on the third dielectric material 992 to fill the second horizontal openings 994. In some embodiments, the fourth dielectric material 993 can be silicon nitride (e.g., trisilicon tetranitride (Si₃N₄)). The fourth dielectric material 993 can be formed using an ALD process to a thickness such that the second horizontal openings 994 are filled (e.g., between 19 and 21nm).

FIG. 9G illustrates an example method, at one stage of a semiconductor fabrication process, for forming extended multi-sided storage nodes in vertical 3D memory, in accordance with a number of embodiments of the present disclosure. As illustrated in FIG. 9G, materials are removed from the vertical opening 985. For instance, the fourth dielectric material 993, the third dielectric material 992, the first conductive material, e.g., first electrode 975, and the polysilicon material 989 are removed from the vertical opening 985. In some embodiments, the fourth dielectric material 993 can be removed from the vertical opening 985 to an end surface of the second horizontal openings 994 using a diluted hydrofluoric acid (e.g., diluted 300:1) and a phosphoric acid (H₃PO₄) etching process, for instance. In some embodiments, the third dielectric material 992 can be removed from the vertical opening 985 to expose the first conductive material 975. The third dielectric material 992 can be recessed using a gas etch process, for instance. In some embodiments, however, the third dielectric material 992 and the first conductive material 975 may be recessed from the vertical opening 985 into the second horizontal openings 994.

According to some embodiments, recessing the first conductive material, e.g., first electrode 975 into the second horizontal opening results in a reduced surface area for the first electrode resulting in lower capacitance for storing charge. The first conductive material 975 may be recessed during an O₂/NH₃ strip process, followed by a diluted hydrofluoric acid (e.g., diluted 500:1), followed by treatment with a hydrochloric acid (HCl)/hydrogen peroxide (H₂O₂) mix (HPM). In some embodiments, the polysilicon material 989 may be recessed from the vertical opening 985 into the second horizontal openings 994 (e.g., by between 9.5 and 10.5nm). The polysilicon material 989 may be recessed during a diluted hydrofluoric acid (e.g., diluted 300:1) and ammonium hydroxide (NH₄OH) treatment.

FIG. 9H illustrates an example method, at one stage of a semiconductor fabrication process, for forming extended multi-sided storage nodes in vertical 3D memory, in accordance with a number of embodiments of the present disclosure. As shown in FIG. 9H, embodiments of the present disclosure can include forming a conductive element 982 onto exposed surfaces of the first electrode 975 to extend the first electrode 975 and the structure of the polysilicon material (e.g., polysilicon material) 989 to an original formation length (d1). For example, the conductive element 982 can extend the length of the first electrode 975 and the polysilicon material 989 to the length of the first electrode 975 and the length of the polysilicon material 989 prior to the etching process described in FIG. 9G.

In one example, forming a conductive element 982 includes selectively depositing molybdenum (Mo) onto exposed surfaces of the first electrode 975 and the polysilicon material 989. In some embodiments Mo 982 is selectively deposited on a first electrode 975 material of titanium nitride (TiN). In some embodiments, selectively depositing Mo 982 onto exposed surface of the first electrode 975 comprises flowing precursors of molybdenum chloride (MoCl₅) and molybdenum dichloride dioxide (MoO₂Cl₂) into the first vertical opening 985 at a temperature in a range of 300 to 1000 degrees Celsius (C). Embodiments, however, for the conductive element 982 are not limited to the example Mo element.

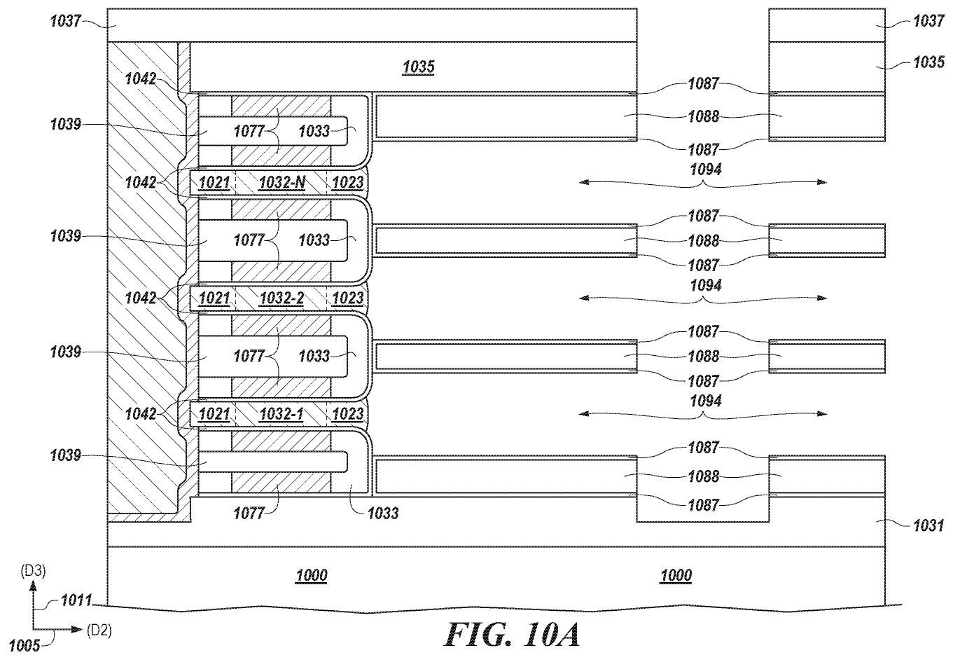

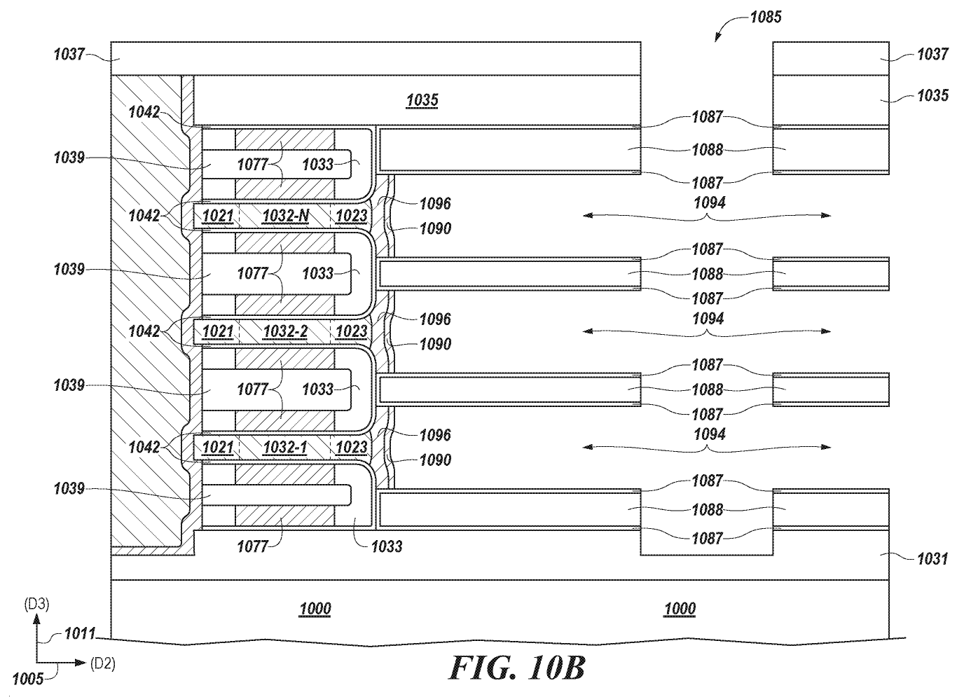

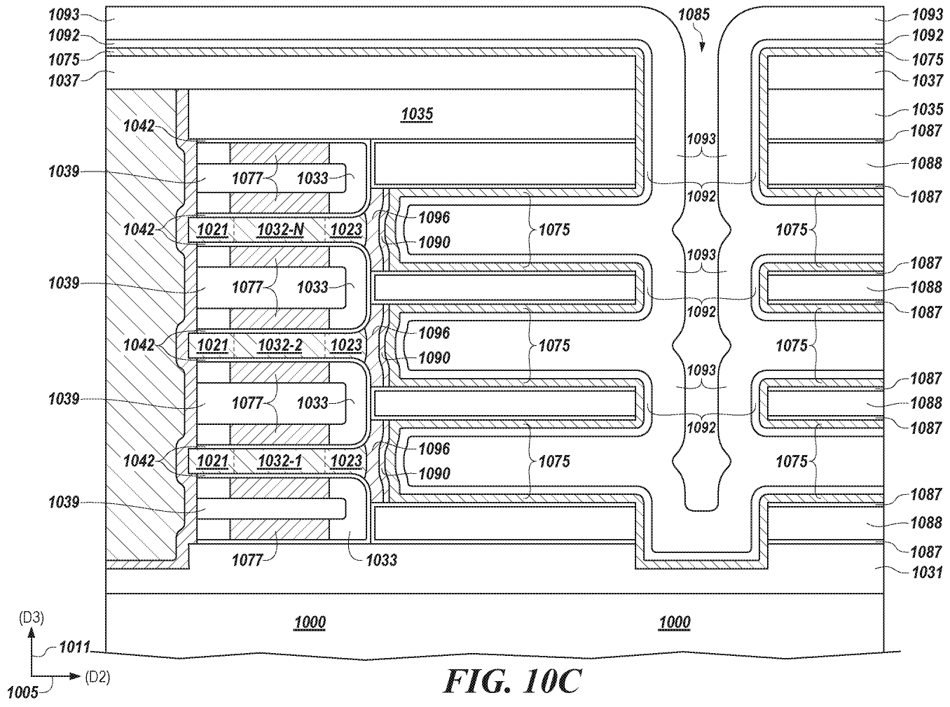

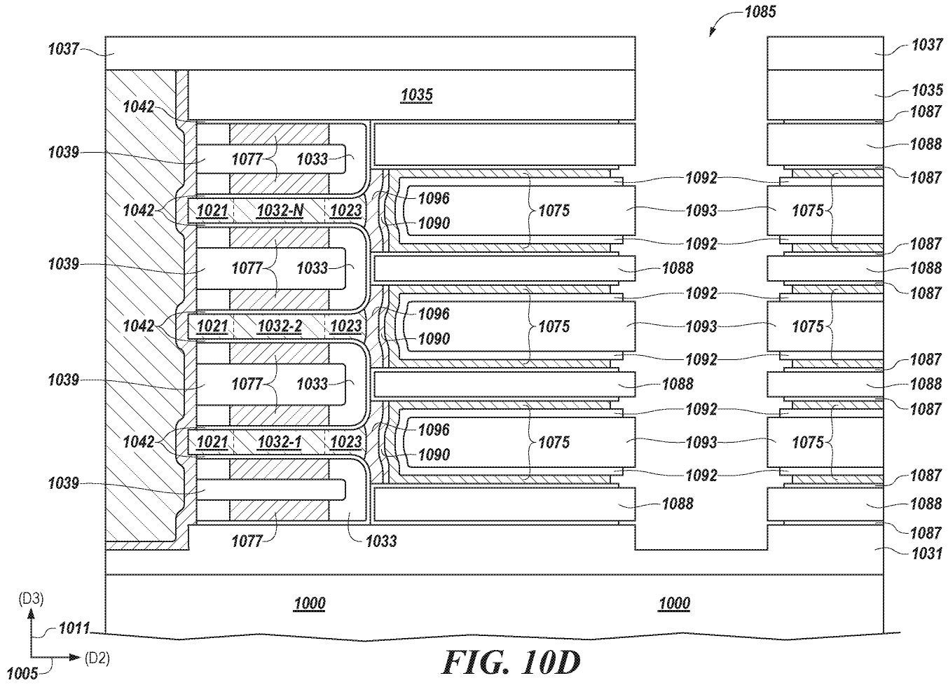

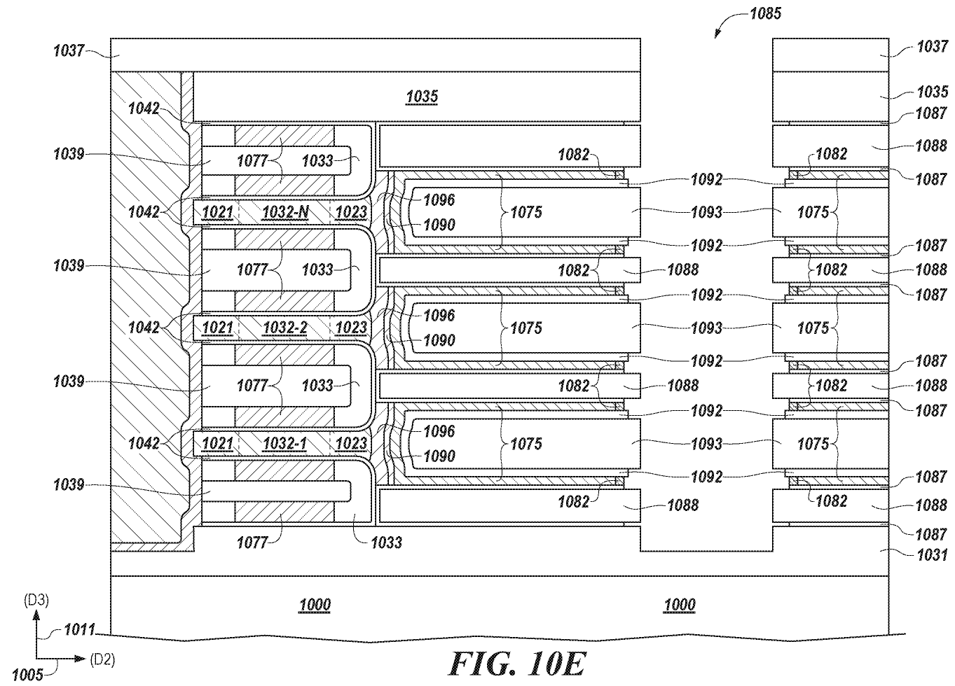

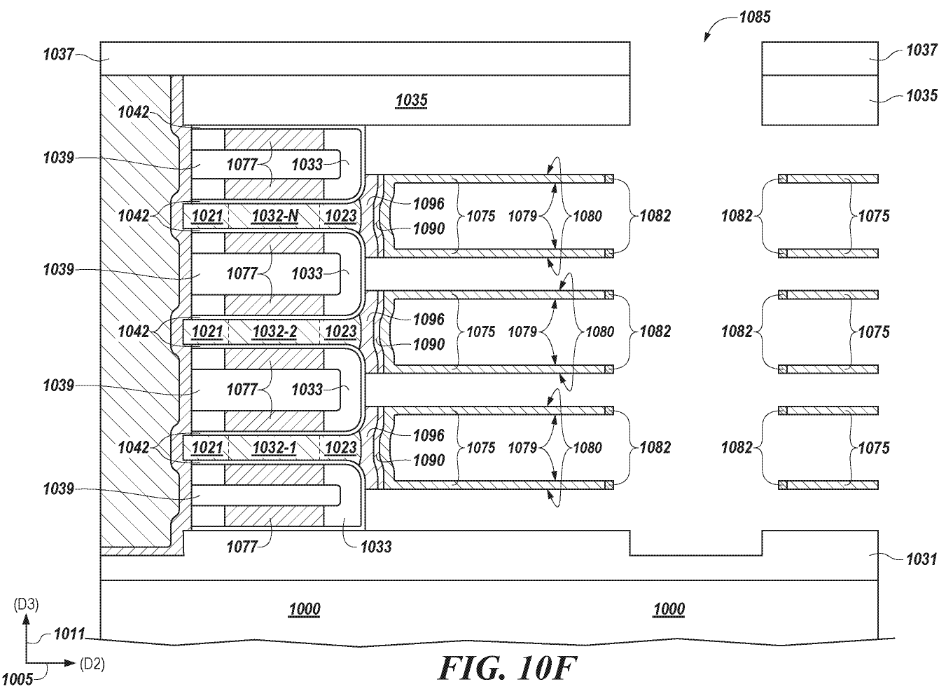

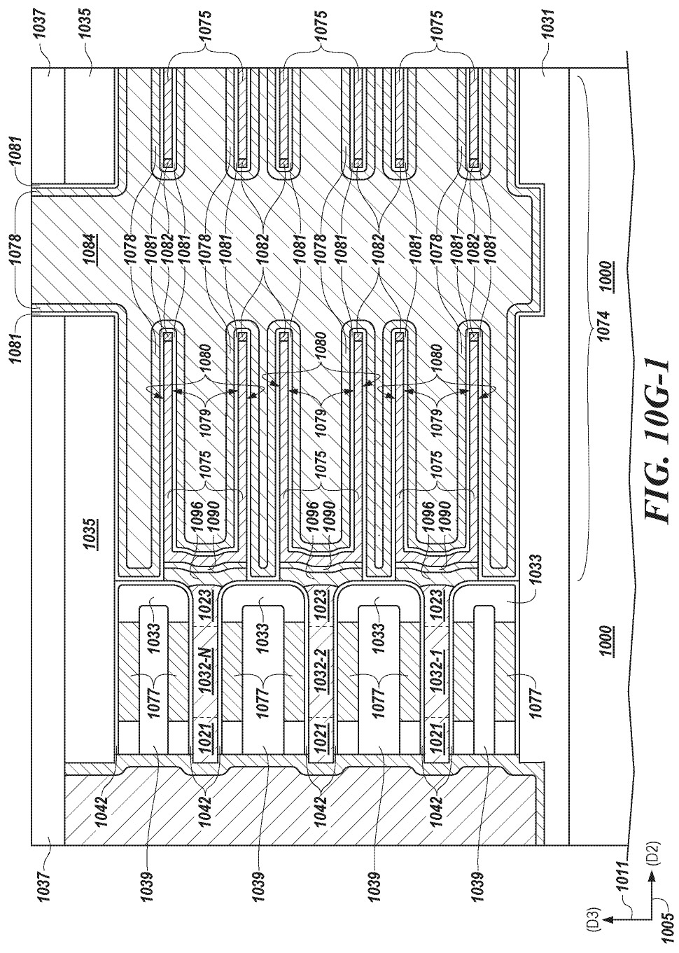

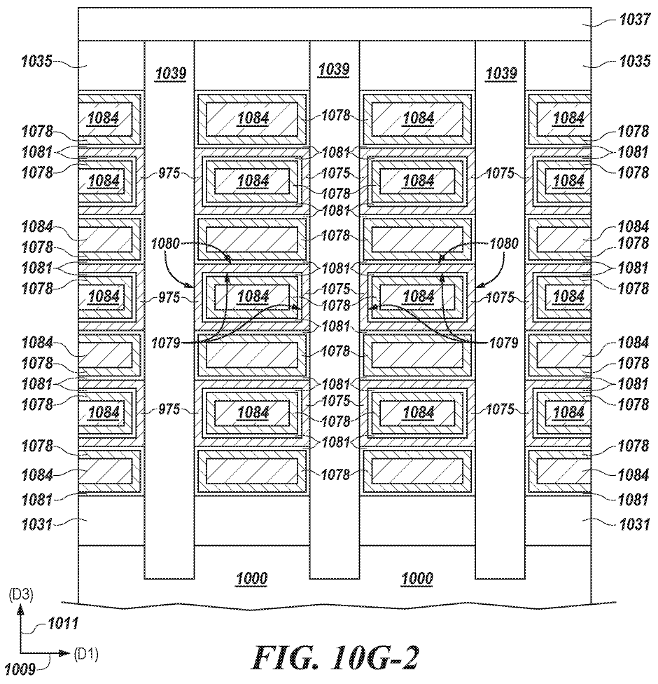

FIG. 9I illustrates an example method, at one stage of a semiconductor fabrication process, for forming extended multi-sided storage nodes in vertical 3D memory, in accordance with a number of embodiments of the present disclosure. As illustrated in FIG. 9I, a portion of the polysilicon material 989 can be removed from the first horizontal openings 986. Remaining doped silicon interface material 983 (e.g., doped silicon material 983 not removed during the stage illustrated in FIG. 9I) is illustrated as the doped silicon material 983 in FIG. 10A. Removal of the portion of the polysilicon material 989 from the first horizontal openings 986 can include using a diluted hydrofluoric acid (e.g., diluted 100:1) treatment followed by a Tetramethylammonium hydroxide (TMAH) treatment.

As further illustrated in FIG. 9I, the first dielectric material 987, the second dielectric material 988, the third dielectric material 992, and the fourth dielectric material 993 can be removed from the first horizontal openings 986 and the second horizontal openings 994. Removing the first dielectric material 987 from the first horizontal openings 986 and the second horizontal openings 994 can include a diluted hydrofluoric acid (e.g., diluted 500:1) treatment. Additional selective etch techniques may be used to remove the second dielectric material 988, the third dielectric material 992, and the fourth dielectric material 993 from the first and second horizontal openings, 986 and 994, as have been described herein. According to embodiments, a resulting first electrode 975, e.g., bottom electrode to a capacitor, structure may result as illustrated in FIG. 9I. Subsequent to the stage of the semiconductor fabrication process illustrated in FIG. 9IH, a storage node 974 can be formed as described in FIG. 9J.

FIG. 9J-1 illustrates a cross-sectional view of a portion of a vertical three-dimensional (3D) memory with extended multi-sided storage nodes in accordance with a number of embodiments of the present disclosure. FIG. 9J-2 illustrates an end-on cross-sectional view of the portion of the vertical three-dimensional (3D) memory illustrated in FIG. 9J-1 in accordance with a number of embodiments of the present disclosure. FIG. 9J-1 and FIG. 9J-2 may be collectively referred to herein as “FIG. 9J.”

The portion illustrated in FIG. 9J includes several components analogous to components previously described in connection with FIGS. 1-8. For instance, illustrated in FIG. 9J are a substrate 900, a fill dielectric 931, first source/drain regions 921, second source/drain regions 923, a second access device dielectric material 933, a first mask material 935, a second mask material 937, a first access device dielectric material 939, a gate dielectric material 942, storage nodes 974, and a horizontal access line conductive material 977.

The storage nodes 974 can each include a first (e.g., bottom) electrode 975. The first electrodes 975 can be made of a first conductive material, e.g., titanium nitride (TiN). Each of the bottom electrodes 975 can be in electrical contact with a respective electrical interface material 983 to a second source/drain region 923. Stated differently, the electrical interface material 983 may reduce resistance and electrically connect the first electrodes 975 to the second source/drain regions 923. The electrical interfaces 983 may be a doped polysilicon material and/or a silicide material, e.g., titanium silicide, that physically and electrically connects the first electrodes 975 to the second source/drain regions 923. As shown in FIG. 9J, the bottom electrodes 975 can extend in a horizontal direction from the electrical interfaces 983.

As shown in FIG. 9J, the first electrode 975 can include an interior portion and an exterior portion. In some embodiments, for instance, the first electrode 975 can include one or more interior surfaces 979 defining an interior of the first electrode 975 and one or more exterior surfaces 980 defining an exterior of the first electrode 975. It is noted that while the example first electrode 975 illustrated in FIG. 9J is substantially rectangular and includes four interior surfaces and four exterior surfaces, embodiments of the present disclosure are not limited to this example. Some embodiments include a single interior surface and a single exterior surface defining a cylindrical first electrode, for instance. Other embodiments include different quantities of surfaces defining differently shaped electrodes.

The first electrodes 975 can be separated from the second electrodes (e.g., top electrodes) 978 by a dielectric material 981. As shown in FIG. 9J, the second electrodes 978 can be separated from the interior surfaces 979 and the exterior surfaces 980 of the first electrodes 975 by the dielectric material 981. In some embodiments, including the example shown in FIG. 9J, the second electrodes 978 are comprised of a single conductive material formed in a vertical direction continuously along the dielectric material 981. This serpentine path, or “folding,” of the second electrodes 978 around both the interiors and the exteriors of the first electrodes 975 can result in the formation of multi-sided storage nodes 974 which may provide an increased effective capacitance and a high capacitance per memory cell. The interstices between folds of the second electrodes 978 can be filled with a plane conductive material 984, which can be coupled to a common electrode plane, such as a ground plane. In some embodiments, the plane conductive material 984 is part of the second electrodes 978. In some embodiments, the plane material is less conductive than material(s) comprising the second electrodes 978. For instance, the plane conductive material 984 can be a boron-doped silicon germanium material and the second electrode material may be titanium nitride (TiN).

As shown FIG. 9J-1, a conductive element 982, e.g., molybdenum (Mo), can be formed on the first electrode 975 to extend the first electrode 975 and increase surface area lost in a semiconductor fabrication process. In some embodiments, the conductive element 982 can extend the first electrode 975 to an original formation length. For example, the conductive element 982 can be formed such that a length of the conductive element 982 and the first electrode 975 is substantially equal to an original deposition and/or formation length of the first electrode 972 prior to the etch process described in FIG. 9G. In one embodiment the first electrode 975 is titanium nitride (TiN) and the conductive element is molybdenum (Mo). Embodiments, however, are not so limited and in some embodiments, the conductive element 982 can be the same material as the first electrode 975 and, in other embodiments, the conductive element 982 can be a different material than the first electrode 975.

As shown in FIG. 9J-1, the conductive element 982 can be formed on the end surface of the first electrode 975, a portion of an upper exterior surface of the first electrode 975, and a portion of a lower exterior surface of the first electrode 975. In some embodiments, a horizontal width (w) 998 of the conductive element 982, as shown in FIG. 9I, can be in a range of 10-200 Angstroms (Å) and a vertical height (h) 999 of the conductive element 982, as shown in FIG. 9I, can be in a range of 40-250Å. In some embodiments, the vertical height (h) 999 of the conductive element 982 can be greater than a height of the first electrode 975.

Referring specifically to FIG. 9J-2, vertical columns of storage nodes (e.g., storage nodes 974 in FIG. 9J-1) can be separated by a dielectric material (e.g., a deep trench isolation structure) 939. Each vertical column can illustrate at least cross section and/or an end portion of the first electrode 975, the second electrode 978, the dielectric material 981, and the plane conductive material 984 of the storage node 974.

FIGS. 10A to 10G illustrate an example method for forming extended multi-sided storage nodes in vertical 3D memory, in accordance with a number of embodiments of the present disclosure. For example, FIG. 10A to 10G can illustrate stages of forming the extended multi-sided storage node illustrated in FIG. 10G.

FIG. 10A illustrates an example method, at one stage of a semiconductor fabrication process, for forming extended multi-sided storage nodes in vertical 3D memory, in accordance with a number of embodiments of the present disclosure. FIG. 10A can be analogous to the processing stage previously described in connection with FIG. 9E, having been preceded by the stages illustrated in FIGS. 9A to 9D, for instance.

As shown in FIG. 10A, the Si material 1032 between the vertical opening and the source/drain regions 1023 can be removed to form second horizontal openings 1094. Removing the Si material 1032 can be carried out by a gas etch process, followed by an O₂/NH₃ strip process, followed by a diluted hydrofluoric acid (e.g., diluted 300:1) and Selis^{TM} vapor etch process, for instance.

FIG. 10B illustrates an example method, at one stage of a semiconductor fabrication process, for forming extended multi-sided storage nodes in vertical 3D memory, in accordance with a number of embodiments of the present disclosure. As illustrated in FIG. 10B, embodiments herein include forming an epitaxially grown Si material 1096 on the second source/drain regions 1023 to an end surface of the second horizontal opening 1094. In some embodiments, the epitaxially grown Si material 1096 can be formed to a thickness in a range of 25-30nm.

As further illustrated in FIG. 10B, a silicide material (e.g., titanium silicide (TiSi) material) 1090 can be formed on the doped silicon material 1092. In some embodiments, the TiSi material 1090 can be formed using a plasma enhanced atomic layer deposition process (PEALD).

FIG. 10C illustrates an example method, at one stage of a semiconductor fabrication process, for forming extended multi-sided storage nodes in vertical 3D memory, in accordance with a number of embodiments of the present disclosure. As illustrated in FIG. 10C, a first conductive material (e.g., titanium nitride (TiN)) 1075, to serve as a first electrode, is formed on the silicide material 1090 and exposed surfaces of the first dielectric material 1087. In some embodiments, the first conductive material 1075 can be a titanium nitride (TiN). In some embodiments, the first conductive material 1075 can include titanium nitride (TiN) and titanium silicon oxynitride (TiSiON). The first conductive material 1075 can be formed to a thickness in a range of 3-9nm. In some embodiments, the first conductive material 1075 can be comprised of a TiN material and a TiSiON material formed on the TiN material. The first conductive material 1075 can be formed using a CVD process at approximately 475 degrees C, for example.

As further illustrated in FIG. 10C, a third dielectric material 1092 (e.g., SiO₂) can be formed on the first conductive material 1075. In some embodiments, the third dielectric material 1092 can be silicon dioxide (SiO₂). The third dielectric material 1092 can be formed to a thickness in a range of 1-3nm using a PEALD process (e.g., XP8®).

As further illustrated in FIG. 10C, a fourth dielectric material 1093 (e.g., Si₃N₄) can be formed on the third dielectric material 1092 to fill the second horizontal openings 1094. In some embodiments, the fourth dielectric material 1093 can be a silicon nitride (e.g., trisilicon tetranitride (Si₃N₄)). The fourth dielectric material 1093 can be formed using an ALD process to a thickness such that the second horizontal openings 1094 are filled (e.g., between 19 and 21nm).

FIG. 10D illustrates an example method, at one stage of a semiconductor fabrication process, for forming extended multi-sided storage nodes in vertical 3D memory, in accordance with a number of embodiments of the present disclosure. As illustrated in FIG. 10D, materials can be removed from the vertical opening 1085. For instance, the fourth dielectric material 1093, the third dielectric material 1092, and the first conductive material 1075 can be removed from the vertical opening 1085. The removal of the fourth dielectric material 1093, the third dielectric material 1092, and the first conductive material 1075 can be carried out in a manner analogous to the removal of the fourth dielectric material 993, the third dielectric material 992, and the first conductive material 975, previously described in connection with FIG. 9G, for instance.

FIG. 10E illustrates an example method, at one stage of a semiconductor fabrication process, for forming extended multi-sided storage nodes in vertical 3D memory, in accordance with a number of embodiments of the present disclosure. In some embodiments, a conductive element 1082 can be selectively deposited only on an exposed end surface of the first electrode 1075 to extend the first electrode 1075 to an original formation length. For example, the conductive element 1082 can extend the first electrode 1075 to a length of the first electrode 1075 previous to the etching process described in FIG. 10D that removes a larger portion of the first electrode 1075 than intended. Further, the conductive element 1082 can be formed to a width of 1-100Å. In some embodiments, the height of the conductive element 1082 can be equal to a height of the first electrode 1075. As stated in reference to FIG. 9, the conductive element 1082 can be a molybdenum material.

FIG. 10F illustrates an example method, at one stage of a semiconductor fabrication process, for forming extended multi-sided storage nodes in vertical 3D memory, in accordance with a number of embodiments of the present disclosure. As illustrated in FIG. 10F, the first dielectric material 1087, the second dielectric material 1088, the third dielectric material 1092, and the fourth dielectric material 1093 can be removed from the first horizontal openings 1086 and second horizontal openings 1094. Removing the first dielectric material 1087, the second dielectric material 1088, the third dielectric material 1092, and the fourth dielectric material 1093 can expose the internal surfaces 1079 of the first electrode 1075 and the external surfaces 1080 of the first electrode 1075. The resultant structure may appear as illustrated in FIG. 10F. Subsequent to the stage of the semiconductor fabrication process illustrated in FIG. 10F, a storage node 1074 can be formed as described in FIG. 10G.

FIG. 10G-1 illustrates a cross-sectional view of a portion of a vertical three-dimensional (3D) memory in accordance with a number of embodiments of the present disclosure. FIG. 10G-2 illustrates an end-on cross-sectional view of the portion of the vertical three-dimensional (3D) memory illustrated in FIG. 10G-1 in accordance with a number of embodiments of the present disclosure. FIG. 10G-1 and FIG. 10G-2 may be collectively referred to herein as “FIG. 10G.”

The portion illustrated in FIG. 10G includes several components analogous to components previously described in connection with FIGS. 1-5. For instance, illustrated in FIG. 10G are a substrate 1000, a fill dielectric 1031, first source/drain regions 1021, second source/drain regions 1023, a second dielectric material 1033, a first mask material 1035, a second mask material 1037, a first dielectric material 1039, a gate dielectric material 1042, storage nodes 1074, and a horizontal access line conductive material 1077.

The storage nodes 1074 can each include a first (e.g., bottom) electrode 1075. The first electrodes 1075 can be made of a first conductive material (e.g., titanium nitride (TiN). Each of the first electrodes 1075 can be in electrical contact with TiSi material 1090 deposited on an epitaxially grown Si material 1096 that is in contact with a second source/drain region 1023. Stated differently, the TiSi material 1090 and the epitaxially grown Si material 1096 can electrically couple the first electrodes 1075 to the second source/drain regions 1023. The TiSi material 1090 and the epitaxially grown Si material 1096 can physically separate the first electrodes 1075 from the second source/drain regions 1023. As shown in FIG. 10F, the first electrodes can extend in a horizontal direction from the epitaxially grown Si material 1096 and the TiSi material 1090.

As shown in FIG. 10G, the first electrode 1075 can include an interior portion 1079 and an exterior portion 1080. In some embodiments, for instance, the first electrode 1075 can include one or more interior surfaces 1079 defining an interior of the first electrode 1075 and one or more exterior surfaces 1080 defining an exterior of the first electrode 1075. It is noted that, while the example first electrode 1075 illustrated in FIG. 10G is substantially rectangular and includes more than one interior surface and more than one exterior surface, embodiments of the present disclosure are not limited to this example. Some embodiments include a single interior surface and a single exterior surface defining a cylindrical first electrode, for instance. Other embodiments include different quantities of surfaces defining differently shaped electrodes. As illustrated in FIG. 10G-1, a conductive element 1082 can be selectively deposited onto an exposed end surface of the first electrodes 1075 to extend each of the first electrodes 1075 to an original formation length.

The first electrodes 1075 can be separated from the second electrodes (e.g., top) electrodes 1078 by a dielectric material 1081. As shown in FIG. 10G, the second electrodes 1078 can be separated from the interior surfaces 1079 and the exterior surfaces 1080 of the first electrodes 1075 by the dielectric material 1081. In some embodiments, including the example shown in FIG. 10G, the second electrodes 1078 can be comprised of a single conductive material formed in a vertical direction continuously along the dielectric material 1081. This serpentine path, or “folding,” of the second electrodes 1078 around both the interiors and the exteriors of the first electrodes 1075 can result in the formation of multi-sided storage nodes which, as previously discussed, provide an increased effective capacitance and a high capacitance per memory cell. The interstices between folds of the second electrodes 1078 can be filled with a plane conductive material 1084, which can be coupled to a common electrode plane, such as a ground plane. In some embodiments, the plane conductive material 1084 can be part of the second electrodes 1078, e.g., top electrodes. In some embodiments, the plane material 1084 can be less conductive than the second conductive material(s) comprising the second electrodes 1078. For instance, the plane conductive material 1084 can be a boron-doped silicon germanium material. Referring specifically to FIG. 10G-2, vertical columns of storage nodes 1074 can be separated by a dielectric material (e.g., a deep trench isolation structure) 1039.

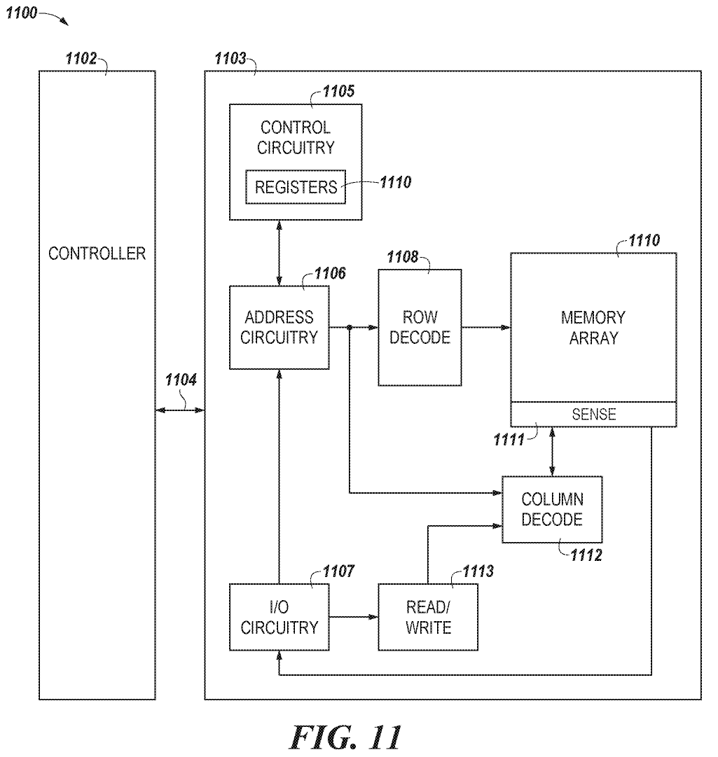

FIG. 11 is a block diagram of an apparatus in the form of a computing system 1100 including a memory device 1103 in accordance with a number of embodiments of the present disclosure. As used herein, a memory device 1103, a memory array 1110, and/or a host (e.g., controller) 1102, for example, might also be separately considered an “apparatus.” According to embodiments, the memory device 1103 may comprise at least one memory array 1110 with a memory cell formed having a digit line and body contact, according to the embodiments described herein.

In this example, system 1100 includes a host 1102 coupled to memory device 1103 via an interface 1104. The computing system 1100 can be a personal laptop computer, a desktop computer, a digital camera, a mobile telephone, a memory card reader, or an Internet-of-Things (IoT) enabled device, among various other types of systems. Host 1102 can include a number of processing resources (e.g., one or more processors, microprocessors, or some other type of controlling circuitry) capable of accessing memory device 1103. The system 1100 can include separate integrated circuits, or both the host 1102 and the memory device 1103 can be on the same integrated circuit. For example, the host 1102 may be a system controller of a memory system comprising multiple memory devices 1103, with the system controller (e.g., control circuitry) 1105 providing access to the respective memory devices 1103 by another processing resource such as a central processing unit (CPU).

In the example shown in FIG. 11, the host 1102 is responsible for executing an operating system (OS) and/or various applications (e.g., processes) that can be loaded thereto (e.g., from memory device 1103 via controller 1105). The OS and/or various applications can be loaded from the memory device 1103 by providing access commands from the host 1102 to the memory device 1103 to access the data comprising the OS and/or the various applications. The host 1102 can also access data utilized by the OS and/or various applications by providing access commands to the memory device 1103 to retrieve said data utilized in the execution of the OS and/or the various applications.

For clarity, the system 1100 has been simplified to focus on features with particular relevance to the present disclosure. The memory array 1110 can be a DRAM array comprising at least one memory cell having a digit line and body contact formed according to the techniques described herein. For example, the memory array 1110 can be an unshielded DL 4F2 array such as a 3D-DRAM memory array. The array 1110 can comprise memory cells arranged in rows coupled by word lines (which may be referred to herein as access lines or select lines) and columns coupled by digit lines (which may be referred to herein as sense lines or data lines). Although a single array 1110 is shown in FIG. 11, embodiments are not so limited. For instance, memory device 1103 may include a number of arrays 1110 (e.g., a number of banks of DRAM cells).

The memory device 1103 includes address circuitry 1106 to latch address signals provided over an interface 1104. The interface can include, for example, a physical interface employing a suitable protocol (e.g., a data bus, an address bus, and a command bus, or a combined data/address/command bus). Such protocol may be custom or proprietary, or the interface 1104 may employ a standardized protocol, such as Peripheral Component Interconnect Express (PCIe), Gen-Z, CCIX, or the like. Address signals are received and decoded by a row decoder 1108 and a column decoder 1112 to access the memory array 1110. Data can be read from memory array 1110 by sensing voltage and/or current changes on the sense lines using sensing circuitry 1111. The sensing circuitry 1111 can comprise, for example, sense amplifiers that can read and latch a page (e.g., row) of data from the memory array 1110. The I/O circuitry 1107 can be used for bi-directional data communication with the host 1102 over the interface 1104. The read/write circuitry 1113 is used to write data to the memory array 1110 or read data from the memory array 1110. As an example, the read/write circuitry 1113 can comprise various drivers, latch circuitry, etc.

Control circuitry 1105 decodes signals provided by the host 1102. The signals can be commands provided by the host 1102. These signals can include chip enable signals, write enable signals, and address latch signals that are used to control operations performed on the memory array 1110, including data read operations, data write operations, and data erase operations. In various embodiments, the control circuitry 1105 is responsible for executing instructions from the host 1102. The control circuitry 1105 can comprise a state machine, a sequencer, and/or some other type of control circuitry, which may be implemented in the form of hardware, firmware, or software, or any combination of the three. In some examples, the host 1102 can be a controller external to the memory device 1103. For example, the host 1102 can be a memory controller which is coupled to a processing resource of a computing device.

The term semiconductor can refer to, for example, a material, a wafer, or a substrate, and includes any base semiconductor structure. “Semiconductor” is to be understood as including silicon-on-sapphire (SOS) technology, silicon-on-insulator (SOI) technology, thin-film-transistor (TFT) technology, doped and undoped semiconductors, epitaxial silicon supported by a base semiconductor structure, as well as other semiconductor structures. Furthermore, when reference is made to a semiconductor in the preceding description, previous process steps may have been utilized to form regions/junctions in the base semiconductor structure, and the term semiconductor can include the underlying materials containing such regions/junctions.

The figures herein follow a numbering convention in which the first digit or digits correspond to the drawing figure number and the remaining digits identify an element or component in the drawing. Similar (e.g., the same) elements or components between different figures may be identified by the use of similar digits. As will be appreciated, elements shown in the various embodiments herein can be added, exchanged, and/or eliminated so as to provide a number of additional embodiments of the present disclosure. In addition, as will be appreciated, the proportion and the relative scale of the elements provided in the figures are intended to illustrate the embodiments of the present disclosure and should not be taken in a limiting sense.

As used herein, “a number of” or a “quantity of” something can refer to one or more of such things. For example, a number of or a quantity of memory cells can refer to one or more memory cells. A “plurality” of something intends two or more. As used herein, multiple acts being performed concurrently refers to acts overlapping, at least in part, over a particular time period. As used herein, the term “coupled” may include electrically coupled, directly coupled, and/or directly connected with no intervening elements (e.g., by direct physical contact), indirectly coupled and/or connected with intervening elements, or wirelessly coupled. The term coupled may further include two or more elements that co-operate or interact with each other (e.g., as in a cause and effect relationship). An element coupled between two elements can be between the two elements and coupled to each of the two elements.

It should be recognized the term vertical accounts for variations from “exactly” vertical due to routine manufacturing, measuring, and/or assembly variations and that one of ordinary skill in the art would know what is meant by the term “perpendicular.” For example, the vertical can correspond to the z-direction. As used herein, when a particular element is “adjacent to” another element, the particular element can cover the other element, can be over the other element or lateral to the other element and/or can be in direct physical contact with the other element. Lateral to may refer to the horizontal direction (e.g., the y-direction or the x-direction) that may be perpendicular to the z-direction, for example.

Although specific embodiments have been illustrated and described herein, those of ordinary skill in the art will appreciate that an arrangement calculated to achieve the same results can be substituted for the specific embodiments shown. This disclosure is intended to cover adaptations or variations of various embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

What is claimed is:

1. A method of forming storage nodes in 3D memory, comprising:
forming an array of vertically stacked memory cells including horizontally oriented access devices and storage nodes, the horizontally oriented access devices having gates formed horizontally at a different level from each other, channel regions, and first source/drain regions and second source/drain regions separated by the channel regions;
forming a horizontal opening adjacent to storage node regions to access the second source/drain regions to deposit a polysilicon material on the second source/drain regions and interior surfaces of the horizontal openings;
depositing a first electrode on the polysilicon material of the horizontal opening;
forming a conductive element onto exposed surfaces of the first electrode to extend the first electrode and the polysilicon; and
forming multi-sided storage nodes having a high-k material on the first electrode and a second electrode on the high-k material.

2. The method of claim 1, wherein forming a conductive element further comprises depositing molybdenum (Mo) onto exposed surfaces of the first electrode.

3. The method of claim 1, further comprising annealing the polysilicon such that dopants from the second source/drain region migrate to the polysilicon to form doped polysilicon as an interface material between the second source/drain regions and the first electrode.

4. The method of claim 1, wherein the method further comprises:
forming a vertical opening through a vertical stack of alternating layers of silicon germanium (SiGe) material and silicon (Si) material adjacent to storage node regions of vertically stacked memory cells;
forming first horizontal openings, wherein forming the first horizontal openings includes removing SiGe material and thinning the Si material between the vertical opening and access device regions;
forming a first dielectric material in the first horizontal opening and forming a second dielectric material on the first dielectric material to fill the first horizontal opening;
forming second horizontal openings, wherein forming the second horizontal openings includes removing the Si material between the vertical opening and the second source/drain regions;
depositing a third dielectric material on the first electrode;
depositing a fourth dielectric material on the third dielectric material to fill the second horizontal openings;
removing the first dielectric material, the second dielectric material, the third dielectric material, and the fourth dielectric material from the first vertical openings; and
removing the first dielectric material, the second dielectric material, the third dielectric material, the fourth dielectric material and the polysilicon material from the first and the second horizontal openings to form the multi-sided storage nodes.

5. The method of claim 4, further comprising thinning the Si material by a vertical distance in a range of 4-5 nanometers (nm).

6. The method of claim 1, further comprising depositing the polysilicon material to a thickness in a range of 5-15nm.

7. The method of claim 1, further comprising depositing the first electrode using chemical vapor deposition (CVD).

8. The method of claim 1, further comprising depositing the first electrode to a thickness in a range of 3-9nm.

9. The method of claim 4, further comprising forming the first dielectric material out of an oxide material, forming the second dielectric material out of a nitride material, and forming the third dielectric material out of the oxide material.

10. A method, comprising:
forming an array of vertically stacked memory cells including horizontally oriented access devices and storage nodes, the horizontally oriented access devices having gates formed horizontally at a different level from each other, channel regions, and first source/drain regions and second source/drain regions separated by the channel regions;
forming a horizontal opening adjacent to storage node regions to access the second source/drain regions;
epitaxially growing doped Si material on the second source/drain regions;
forming a first electrode on the epitaxially grown doped Si material in the horizontal opening;
selectively depositing a conductive element onto an exposed end surface of the first electrode to extend the first electrode to an original formation length; and
forming multi-sided storage nodes having a high-k material on the first electrode and forming a second electrode on the high-k material.

11. The method of claim 10, wherein selectively depositing a conductive element comprises selectively depositing molybdenum (Mo) onto exposed surfaces of the first electrode.

12. The method of claim 10, wherein selectively depositing Mo onto exposed surface of the first electrode comprises flowing precursors of molybdenum chloride (MoCl5) and molybdenum dichloride dioxide (MoO₂Cl₂) into the first vertical opening at a temperature in a range of 300 to 1000 degrees Celsius (C).

13. The method of claim 10, further comprising epitaxially growing the doped Si material to a thickness in a range of 25-30 nanometers (nm).

14. The method of claim 10, further epitaxially growing the doped Si material comprises forming a titanium silicide (TiSix) material on the second source/drain regions.

15. The method of claim 14, further comprising forming the TiSix material using a plasma enhanced atomic layer deposition (PEALD).

16. The method of claim 10, the method further comprising:
forming a vertical opening through a vertical stack of alternating layers of silicon germanium (SiGe) material and silicon (Si) material and adjacent to storage node regions of the vertically stacked memory cells;
removing SiGe material and thinning the Si material between the vertical opening and access device regions to form first horizontal openings;
depositing a first dielectric material in the first horizontal openings and forming a second dielectric material on the first dielectric material to fill the first horizontal openings;
removing the Si material between the vertical opening and the source/drain regions to form second horizontal openings;
forming a third dielectric material on the first electrode material;
forming a fourth dielectric material on the third dielectric material to fill the second horizontal openings;
removing the first dielectric material, the second dielectric material, the third dielectric material, and the fourth dielectric material from the first vertical openings; and
removing the first dielectric material, the second dielectric material, the third dielectric material, and the fourth dielectric material from the first horizontal openings and the second horizontal openings to form the multi-sided storage nodes.

17. The method of claim 16, further comprising forming the third dielectric material to a thickness in a range of 1-3nm.

18. A memory device, comprising:
an array of vertically stacked memory cells, comprising:
horizontally oriented access devices, the horizontally oriented access devices having gates formed horizontally at a different level from each other, channel regions, and first source/drain regions and second source/drain regions separated by the channel regions; and
horizontally oriented storage nodes, wherein each storage node includes:
a first electrode, extending in a horizontal direction from, and in electrical contact with, an interface material in contact with the second source/drain region of a given one of the vertically stacked memory cells, the first electrode having interior and exterior surfaces,
a conductive element of a different type than the first electrode formed on an end surface of the first electrode;
a dielectric material formed on the first electrode and the conductive element; and
a second electrode separated from the interior and exterior surfaces of the first electrode by the dielectric material, wherein the second electrode is formed continuously in a vertical direction along the vertically stacked memory cells.

19. The memory device of claim 18, wherein the conductive element is molybdenum (Mo).

20. The memory device of claim 19, wherein the first electrode is titanium nitride (TiN).

21. The memory device of claim 18, wherein the interface material is a titanium silicide (TiSix).

22. The memory device of claim 19, wherein the conductive element is formed on the end surface of the first electrode, a portion of an upper exterior surface of the first electrode, and a portion of a lower exterior surface of the first electrode.

23. The memory device of claim 22, wherein a horizontal width (w) of the conductive element is in a range of 10-200 Angstroms (Å).

24. The memory device of claim 22, wherein a vertical height (h) of the conductive element is in a range of 40-250 Å.

25. The memory device of claim 24, wherein the vertical height (h) of the conductive element is greater than a vertical height of the first electrode.

26. The memory device of claim 19, wherein the conductive element is only formed on the end surface of the first electrode and has a horizontal width (w) in a range of 1-100 Å.

27. The memory device of claim 26, wherein a vertical height (h) of the conductive element is equal to a height of the first electrode.
